(19) United States
(12) Patent Application Publication
(10) Pub. No.: US 2026/0026068 A1
(43) Pub. Date: Jan. 22, 2026

(54) SEMICONDUCTOR DEVICE AND MANUFACTURING METHOD THEREOF

(71) Applicant: Samsung Electronics Co., Ltd., Suwon-si (KR)

(72) Inventors: Sanghyun KIM, Suwon-si (KR); In Jun HWANG, Suwon-si (KR)

(73) Assignee: Samsung Electronics Co., Ltd., Suwon-si (KR)

(21) Appl. No.: 19/027,773

(22) Filed: Jan. 17, 2025

(30) Foreign Application Priority Data
Jul. 19, 2024 (KR) 10-2024-0095563

(51) Int. Cl. H10D 64/00; H10D 30/01; H10D 30/47

(52) U.S. Cl. CPC H10D 64/112; H10D 30/015; H10D 30/471

(57) ABSTRACT

A semiconductor device includes: a channel layer; a barrier layer disposed on the channel layer; a gate electrode disposed on the barrier layer; a source electrode and a drain electrode connected to the channel layer and on respective sides of the gate electrode; lower field distribution patterns spaced between the gate electrode and the drain electrode; and an upper field distribution pattern spaced from the lower field distribution patterns on the lower field distribution patterns, and connected to the source electrode.

### CROSS-REFERENCE TO RELATED APPLICATION

This application claims priority to and the benefit of Korean Patent Application No. 10-2024-0095563 filed in the Korean Intellectual Property Office on Jul. 19, 2024, the entire contents of which are incorporated herein by reference.

### BACKGROUND

Some example embodiments relate to a semiconductor device and/or a manufacturing method thereof.

In the modern society, semiconductor devices are often used in daily life. In particular, the importance of power semiconductor devices used in various fields such as transportation fields, such as electric vehicles, railways, and electric trams, renewable energy systems, such as solar power generation and wind power generation, and mobile devices is gradually increasing. The power semiconductor device is used to control high voltages and/or high currents, and may perform functions such as electric power conversion and/or control in large electric power systems or high-power electronic devices. The power semiconductor devices have the ability and durability to process high electric power, process large amounts of current, and withstand high voltages. For example, the power semiconductor device may process voltages of hundreds to thousands of volts and currents of tens to thousands of amperes. The power semiconductor devices may improve the efficiency of electrical energy by reducing or minimizing power loss. The power semiconductor devices may be operated stably in environments such as high temperatures.

These power semiconductor devices may be classified according to materials, and for example, they may include a silicon-carbide (SiC) power semiconductor device and a gallium-nitride (GaN) electric power semiconductor device. By manufacturing the power semiconductor devices using SiC or GaN instead of existing silicon wafers (Si wafers), the drawbacks of silicon, which has unstable characteristics at high temperatures, may be compensated or at least partly compensated. The SiC power semiconductor devices are resistant to high temperatures and/or have low power loss, and may be suitable for electric vehicles, renewable energy systems, etc. The GaN power semiconductor devices may have high costs, but are efficient in terms of speed and may be suitable for high-rate charging of mobile devices.

### SUMMARY

Some example embodiments attempt to provide a semiconductor device manufactured by an improved process, and/pr a manufacturing method thereof.

Example embodiments are not limited to the effects mentioned above, and other technical tasks not mentioned can be clearly understood by those of ordinary skill in the art from the description provided below.

Some example embodiments may provide a semiconductor device including: a channel layer; a barrier layer on the channel layer; a gate electrode on the barrier layer; a source electrode and a drain electrode connected to the channel layer and on respective sides of the gate electrode; lower field distribution patterns spaced and disposed between the gate electrode and the drain electrode; and an upper field distribution pattern spaced from the lower field distribution patterns and on the lower field distribution patterns, and connected to the source electrode.

Alternatively or additionally, some example embodiments may provide a method of manufacturing a semiconductor device including: forming a channel layer on a substrate; forming a barrier layer on the channel layer; forming a gate semiconductor layer on the barrier layer; forming a first passivation layer for covering the barrier layer and the gate semiconductor layer; forming lower field distribution patterns spaced from each other and disposed on the first passivation layer in the first direction; forming a second passivation layer for covering the lower field distribution patterns; and forming upper field distribution patterns at let partly overlapping at least a first region of the lower field distribution patterns in a thickness direction on the second passivation layer.

Alternatively or additionally, some example embodiments may provide a substrate; a buffer layer on the substrate; a channel layer disposed on the buffer layer; a barrier layer on the channel layer; a gate electrode on the barrier layer; a gate semiconductor layer between the barrier layer and the gate electrode; a first passivation layer on the barrier layer, and covering the gate electrode and the gate semiconductor layer; lower field distribution patterns between the gate electrode and the drain electrode on the first passivation layer, and spaced from each other and arranged in a first direction; a second passivation layer for covering the lower field distribution patterns; a source electrode and a drain electrode penetrating the first passivation layer and the second passivation layer, connected to the channel layer, and on respective sides of the gate electrode; and an upper field distribution pattern spaced from the lower field distribution patterns and disposed on the lower field distribution patterns, and connected to the source electrode.

The semiconductor device according to some example embodiments may include an upper field distribution pattern, and lower field distribution patterns disposed below the upper field distribution pattern, and lower field distribution patterns float. According to some example embodiments, the various field distribution pattern structures with different field distribution effects may be manufactured with a more simplified process.

### BRIEF DESCRIPTION OF THE DRAWINGS

FIG. 1 shows a top plan view of a semiconductor device according to some example embodiments.

FIG. 2 and FIG. 3 show cross-sectional views of a semiconductor device according to some example embodiments.

FIG. 4 shows a top plan view of a semiconductor device according to some example embodiments.

FIG. 5 and FIG. 6 show a semiconductor device according to some example embodiments.

FIG. 7 and FIG. 8 show a semiconductor device according to some example embodiments.

FIG. 9 and FIG. 10 show a semiconductor device according to some example embodiments.

FIG. 11 and FIG. 12 show a semiconductor device according to some example embodiments.

FIG. 13 shows a semiconductor device according to some example embodiments.

FIG. 14 to FIG. 22 show cross-sectional views of a process for manufacturing a semiconductor device in process order according to some example embodiments.

FIG. 23 shows a cross-sectional view of a semiconductor device manufactured by a manufacturing process that is different from a manufacturing process described with reference to FIG. 14 to FIG. 22.

FIG. 24 shows a cross-sectional view of a semiconductor device manufactured by a manufacturing process that is different from a manufacturing process described with reference to FIG. 14 to FIG. 22 and FIG. 23.

### DETAILED DESCRIPTION

Some example embodiments will be described more fully hereinafter with reference to the accompanying drawings, in which some example embodiments are shown. As those of ordinary skill in the art would realize, the described example embodiments may be modified in various different ways, all without departing from the spirit or scope of inventive concepts.

Parts that are irrelevant to the description will be omitted to clearly describe the present disclosure, and the same elements will be designated by the same reference numerals throughout the specification.

The size and/or thickness of each configuration shown in the drawings are arbitrarily shown for better understanding and ease of description, but the present invention is not limited thereto. In the drawings, the thickness of layers, films, panels, regions, etc., are enlarged for clarity. The thicknesses of some layers and areas may be exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is perpendicularly cut from the side.

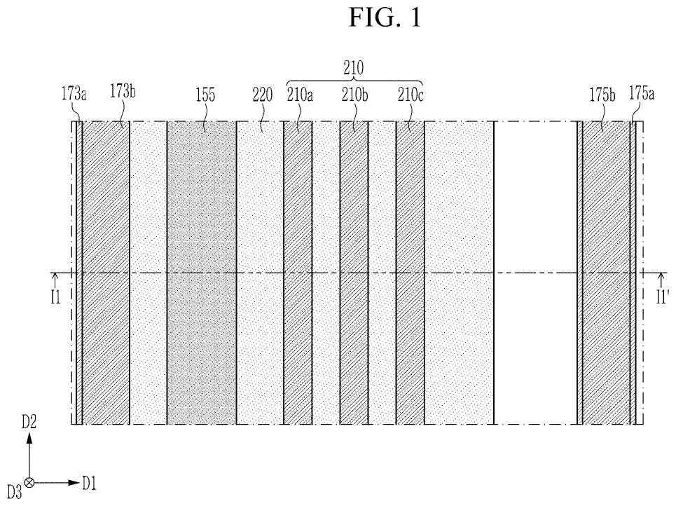

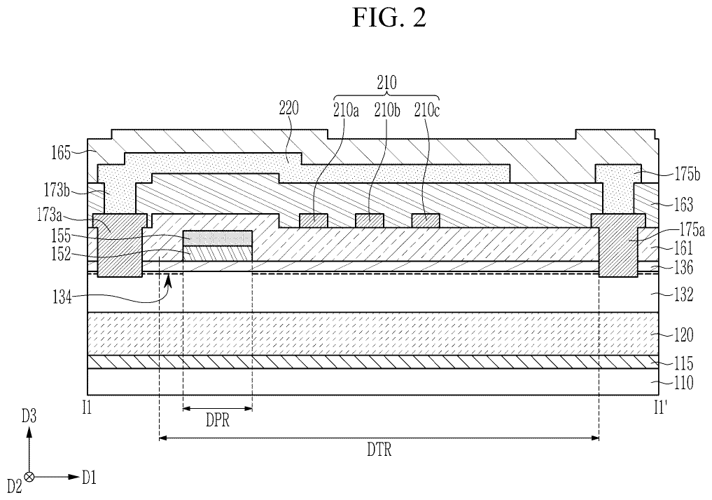

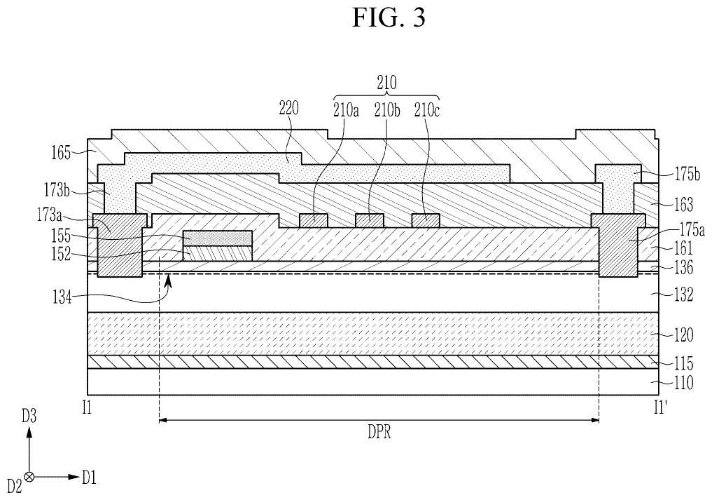

FIG. 1 to FIG. 3 show a semiconductor device according to some example embodiments. In detail, FIG. 1 shows a top plan view of a semiconductor device according to some example embodiments. FIG. 2 and FIG. 3 show cross-sectional views of a semiconductor device with respect to a line I1-I1′ of FIG. 1 according to some example embodiments.

As shown in FIG. 1 to FIG. 3, the semiconductor device may include a channel layer 132, a barrier layer 136 disposed on the channel layer 132, a gate electrode 155 disposed on the barrier layer 136, a source electrode 173 and a drain electrode 175 disposed on respective sides of the gate electrode 155 and connected to the channel layer 132, lower field distribution patterns 210 disposed between the gate electrode 155 and the drain electrode 175, and an upper field distribution pattern 220 disposed on the lower field distribution patterns 210.

The channel layer 132 may form a channel between the source electrode 173 and the drain electrode 175, and a 2-dimensional electron gas (2DEG) 134 may be disposed in or formed in the channel layer 132, e.g., during operation thereof. The 2-dimensional electron gas 134 may be or may include or correspond to a charge transport model used in the solid physics, and may represent a group of electrons moving freely in the two dimensions (e.g., x-y plane direction) but not moving in another dimensions (e.g., z-direction), while being tightly bound in the two dimensions. For example, the two-dimensional electron gas 134 may exist in a 2-dimensional paper-like form in a 3-dimensional space. The 2-dimensional electron gas 134 may mainly appear in a semiconductor heterojunction structure, and may be generated at an interface between the channel layer 132 and the barrier layer 136 in the semiconductor device according to some example embodiments. For example, the 2-dimensional electron gas 134 may be generated in a portion that is adjacent to the barrier layer 136 in the channel layer 132.

The channel layer 132 may include one or more materials selected from the Group III-V materials, for example, nitrides containing Al, Ga, In, B, or combinations thereof. The channel layer 132 may be a single layer or a multilayer. The channel layer 132 may be AlₓIn_{y}Ga_{1-x-y}N (0≤x≤1, 0≤y≤1, x+y≤1). For example, the channel layer 132 may include at least one of AlN, GaN, InN, InGaN, AlGaN, AlInN, and AlInGaN. The channel layer 132 may be a layer with doped impurities or a layer with undoped impurities. A thickness of the channel layer 132 may be about several hundred nm or less.

The channel layer 132 may be disposed on the substrate 110, and a seed layer 115 and a buffer layer 120 may be disposed between the substrate 110 and the channel layer 132. The substrate 110, the seed layer 115, and the buffer layer 120 may be used to form the channel layer 132, and at least one of the substrate 110, the seed layer 115, and the buffer layer 132 may be omitted in some cases. For example, when the substrate made of GaN is used as the channel layer 132, at least one of the substrate 110, the seed layer 115, and the buffer layer 120 may be omitted. Considering that a price of the substrate made of GaN may relatively high, the channel layer 132 containing GaN may be grown, e.g., seeded and/or epitaxially grown, using the substrate 110 made of Si. The lattice structure of Si and the lattice structure of GaN are different and growing the channel layer 132 on the substrate 110 may not be easy. Accordingly, the seed layer 115 and the buffer layer 120 may be first grown on the substrate 110, and then the channel layer 132 may be grown on the buffer layer 120. At least one of the substrate 110, the seed layer 115, and the buffer layer 120 may be removed from the final structure of the semiconductor device after being used in the manufacturing process.

The substrate 110 may include a semiconductor material. For example, the substrate 110 may include sapphire, Si, SiC, AlN, GaN, and combinations thereof. The substrate 110 may be or may include a silicon on insulator (SOI) substrate. However, the material of substrate 110 is not limited to this, and any generally-used substrates may be applied. In some cases, the substrate 110 may include an insulating material. For example, several layers including the channel layer 132 may be formed on the semiconductor substrate, the semiconductor substrate may be removed, and may be replaced with an insulation substrate.

The seed layer 115 may be disposed on the substrate 110. The seed layer 115 may be disposed just on the substrate 110. Without being limited to this, another layer such as another predetermined layer may be further disposed between the substrate 110 and the seed layer 121. The seed layer 115 may serve as a seed for growing the buffer layer 120, and may be made of a crystal lattice structure that becomes the seed of the buffer layer 120. For example, the seed layer 115 may include AlN, but is not limited thereto.

The buffer layer 120 may be disposed on the seed layer 115. The buffer layer 120 may be disposed just on the seed layer 115. Without being limited to this, other layers such as other predetermined layers may be further disposed between the seed layer 115 and the buffer layer 120. The buffer layer 120 may be disposed between the seed layer 115 and the channel layer 132. The buffer layer 120 may include one or more materials selected from among the Group III-V materials, for example, nitrides containing at least one of Al, Ga, In, and B. The buffer layer 120 may be AlₓIn_{y}Ga_{1-x-y}N (0≤x≤1, 0≤y≤1, x+y≤1). For example, the buffer layer 120 may include at least one of AlN, GaN, InN, InGaN, AlGaN, AlInN, and AlInGaN. The buffer layer 120 may be a single layer or a multilayer. Although not clearly shown in FIG. 1 to FIG. 3, the buffer layer 120 may further include a superlattice layer and a high resistance layer.

The superlattice layer may alleviate or at least partially alleviate a difference in a lattice constant and/or a thermal expansion coefficient between the substrate 110 and the channel layer 132, and may thereby alleviate or at least partially alleviate a tensile stress and/or a compressive stress generated between the substrate 110 and the channel layer 132. The superlattice layer may include one or more materials selected from the Group III-V materials, for example, nitrides containing at least one of Al, Ga, In, and B. For example, the superlattice layer may have a structure in which a layer made of AlGaN and a layer made of GaN are repeatedly stacked.

The high resistance layer may prevent or reduce the likelihood of and/or impact of a semiconductor device according to some example embodiments from being degraded by preventing a leakage current from flowing through the channel layer 132. The high resistance layer may be made of a material with low conductivity so that the substrate 110 may be electrically insulated from the channel layer 132. The high resistance layer may include one or more materials selected from the Group III-V materials, for example, nitrides containing Al, Ga, In, B, or combinations thereof. For example, the high resistance layer may include at least one of AlN, GaN, InN, InGaN, AlGaN, AlInN, an AlInGaN. The high resistance layer may be a single layer or a multilayer. The high resistance layer may be a layer with undoped impurities. Without being limited to this, the high resistance layer may include impurities. The buffer layer 120 may further include other layers in addition to the superlattice layer and the high resistance layer.

The barrier layer 136 may be disposed on the channel layer 132. The barrier layer 136 may be disposed just on the channel layer 132. Without being limited to this, other layers such other predetermined other layers may be further disposed between the channel layer 132 and the barrier layer 136. A region of the channel layer 132 overlapping the barrier layer 136 may be or may correspond to a drift region DTR. The drift region DTR may be disposed between the source electrode 173 and the drain electrode 175. Carriers may move in the drift region DTR when a potential difference is generated between the source electrode 173 and the drain electrode 175. The semiconductor device may be turned on/off according to whether a voltage is applied to the gate electrode 155 and according to a size of the voltage applied to the gate electrode 155. When a voltage that is equal to or greater than a threshold voltage is applied to the gate electrode 155 and the semiconductor device is turned on, a channel may be generated in a depletion region DPR. Hence, the carriers may move in the drift region DTR. When a voltage that is lower than the threshold voltage is applied to the gate electrode 155 or no voltage is applied thereto, a channel path may be blocked or at least partially blocked and the carriers may not move or may not significantly move in the depletion region DPR.

The barrier layer 136 may include one or more materials selected from the Group III-V materials, for example, nitrides containing Al, Ga, In, B, or combinations thereof. The barrier layer 136 may be AlₓIn_{y}Ga_{1-x-y}N (0≤x≤1, 0≤y≤1, x+y≤1). The barrier layer 136 may include at least one of GaN, InN, AlGaN, AlInN, InGaN, AlN, and AlInGaN. An energy band gap of the barrier layer 136 may be adjusted by a composition ratio of Al and/or In.

The barrier layer 136 may include a semiconductor material with a characteristic that is different from the channel layer 132. The barrier layer 136 may be different from the channel layer 132 in at least one of a polarization characteristic, an energy band gap, and a lattice constant. For example, the barrier layer 136 may include a material with a different energy band gap from the channel layer 132. The barrier layer 136 may have a higher energy band gap than the channel layer 132, and may have higher electrical polarizability than the channel layer 132. By the barrier layer 136, the 2-dimensional electron gas 134 may be generated to the channel layer 132 which has relatively low electrical polarizability. In this respect, the barrier layer 136 may also be referred to as a channel supply layer and/or as a 2-dimensional electron gas supply layer. The 2-dimensional electron gas 134 may be formed in a portion of the channel layer 132 disposed below an interface between the channel layer 132 and the barrier layer 136. The 2-dimensional electron gas 134 may have very high electron mobility.

The gate electrode 155 may be disposed on the barrier layer 136. The gate electrode 155 may overlap or at least partially overlap a region such as a predetermined region of the barrier layer 136. The gate electrode 155 may overlap or at least partially overlap a portion of the drift region DTR of the channel layer 132. The gate electrode 155 may be disposed between the source electrode 173 and the drain electrode 175. The gate electrode 155 may be spaced from the source electrode 173 and the drain electrode 175 in the first direction D1. The first direction D1 may be parallel to an upper surface of the substrate 110 or an upper surface of the channel layer 132. Referring to FIG. 1 to FIG. 3, the gate electrode 155 may be disposed nearer the source electrode 173 between the source electrode 173 and the drain electrode 175. For example, a spaced distance between the source electrode 173 and the gate electrode 155 may be less than a spaced distance between the drain electrode 175 and the gate electrode 155. Without being limited to this, the position of the gate electrode 155 may be changeable in many ways. For example, the gate electrode 155 may be substantially disposed in a center between the source electrode 173 and the drain electrode 175, or may be disposed nearer to the drain electrode 175 than to the source electrode 173.

The gate electrode 155 may extend in a second direction D2 that is different from the first direction D1 in a plan view. The second direction D2 may be parallel to the upper surface of the substrate 110 or the upper surface of the channel layer 132, and may cross the first direction D1. For example, the second direction D2 may be perpendicular to the first direction D1. The gate electrode 155 may have a bar shape extending in the second direction D2.

The gate electrode 155 may include a conductive material. For example, the gate electrode 155 may include one or more of a metal, a metal alloy, a conductive metal nitride, a metal silicide, a doped semiconductor material such as but not limited to doped polysilicon, a conductive metal oxide, or a conductive metal oxynitride. For example, the gate electrode 155 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide (TiAlC—N), titanium aluminum carbide (TiAlC), titanium carbide (TiC), tantalum carbide (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The gate electrode 155 may be a single layer or a multilayer.

The semiconductor device may further include a gate semiconductor layer 152 disposed between the barrier layer 136 and the gate electrode 155. The gate semiconductor layer 152 may be disposed on the barrier layer 136. The gate electrode 155 may be disposed on the gate semiconductor layer 152. The gate electrode 155 may contact the gate semiconductor layer 152. A bottom surface of the gate electrode 155 may contact the gate semiconductor layer 152. Without being limited to this, another layer such as another predetermined layer may be further disposed between the gate electrode 155 and the gate semiconductor layer 152. The gate electrode 155 may Schottky-contact the gate semiconductor layer 152. Without being limited to this, depending on cases, in some example embodiments the gate electrode 155 may ohmic-contact the gate semiconductor layer 152. The gate semiconductor layer 152 may overlap or at least partially overlap the gate electrode 155 in the third direction D3. The third direction D3 may be perpendicular to the first direction D1 and the second direction D2. For example, the third direction D3 may be perpendicular to the upper surface of the substrate 110 or the upper surface of the channel layer 132. The gate electrode 155 may be patterned using a same mask as the gate semiconductor layer 152. Therefore, the gate electrode 155 may have substantially the same planar shape as the gate semiconductor layer 152. The gate electrode 155 may have substantially the same width as the gate semiconductor layer 152.

The gate semiconductor layer 152 may be disposed between the source electrode 173 and the drain electrode 175. The gate semiconductor layer 152 may be spaced from the source electrode 173 and the drain electrode 175. The gate semiconductor layer 152 may be disposed nearer to the source electrode 173 between the source electrode 173 and the drain electrode 175. For example, the spaced distance between the source electrode 173 and the gate semiconductor layer 152 may be less than the spaced distance between the drain electrode 175 and the gate semiconductor layer 152. Without being limited to this, the position of the gate semiconductor layer 152 may be changeable in many ways. For example, the gate semiconductor layer 152 may be substantially disposed in the center between the source electrode 173 and the drain electrode 175, or may be disposed nearer the drain electrode 175 than to the source electrode 173.

The gate semiconductor layer 152 may include one or more materials selected from the Group III-V materials, for example, nitrides containing Al, Ga, In, B, or combinations thereof. The gate semiconductor layer 152 may be AlₓIn_{y}Ga_{1-x-y}N (0≤x≤1, 0≤y≤1, x+y≤1). For example, the gate semiconductor layer 152 may include at least one of AlN, GaN, InN, InGaN, AlGaN, AlInN, and AlInGaN. The gate semiconductor layer 152 may include a material with a different energy band gap from the barrier layer 136. For example, the gate semiconductor layer 152 may include GaN, and the barrier layer 136 may include AlGaN. The gate semiconductor layer 152 may be doped with impurities such as predetermined impurities. The impurities doped to the gate semiconductor layer 152 may be or may include p-type impurities providing holes. For example, the gate semiconductor layer 152 may include GaN to which p-type impurities are doped. For example, the gate semiconductor layer 152 may be made of a p-GaN layer. Without being limited to this, the gate semiconductor layer 152 may be a p-AlGaN layer. In some examples, the gate semiconductor layer 152 may be doped with both p-type impurities and n-type impurities, and a concentration of the p-type impurities may be higher than, e.g., several orders of magnitude higher than, a concentration of the n-type impurities. For example, the impurity doped to the gate semiconductor layer 152 may be magnesium (Mg). The gate semiconductor layer 152 may be a single layer or a multilayer.

A depletion region DPR may be formed in the channel layer 132 by the gate semiconductor layer 152. The depletion region DPR may be disposed in the drift region DTR, and may have a less width than the drift region DTR. As the gate semiconductor layer 152 with the different energy band gap from the barrier layer 136 is disposed on the barrier layer 136, a level of the energy band on the portion of the barrier layer 136 overlapping the gate semiconductor layer 152 may be increased. Hence, a depletion region DPR may be formed in a region of the channel layer 132 overlapping the gate semiconductor layer 152. The depletion region DPR may be or may correspond to a region in which the 2-dimensional electron gas 134 is not formed or which has a lower concentration of electrons than other regions from among the channel path of the channel layer 132. For example, the depletion region DPR may represent a region where the flow of two-dimensional electron gas 134 is disconnected in the drift region DTR. As the depletion region DPR is generated, no current may flow between the source electrode 173 and the drain electrode 175, and the channel path may be blocked. Hence, the semiconductor device may have a normally-off characteristic.

For example, the semiconductor device may be a normally-off high electron mobility transistor (HEMT). In a normal state in which no voltage is applied to the gate electrode 155, there is a depletion region DPR, and the semiconductor device may be turned off. When a voltage that is equal to or greater than a threshold voltage is applied to the gate electrode 155, the depletion region DPR may disappear, and the 2-dimensional electron gas 134 may not be connected but may be connected in the drift region DTR. For examples, the 2-dimensional electron gas 134 may be formed in the channel path between the source electrode 173 and the drain electrode 175, and the semiconductor device may be turned on. The semiconductor device may include semiconductor layers with different electrical polarization characteristics, and the semiconductor layer with relatively greater polarization may generate the 2-dimensional electron gas 134 to another semiconductor layer hetero-contacting with it. The 2-dimensional electron gas 134 may be used as a channel between the source electrode 173 and the drain electrode 175, and continuation or interruption of the flow of the 2-dimensional electron gas 134 may be controlled by a bias voltage applied to the gate electrode 155. In a gate Off state, a flow of the 2-dimensional electron gas 134 may be blocked, and no current may flow between the source electrode 173 and the drain electrode 175. When the flow of the 2-dimensional electron gas 134 continues in a gate On state, the current may flow between the source electrode 173 and the drain electrode 175.

In the above, the case in which the semiconductor device according to some example embodiments is a normally off high electron mobility transistor has been described, but is not limited thereto. For example, the semiconductor device according to some example embodiments may be a normally-on high electron mobility transistor.

The above-noted buffer layer 120, the channel layer 132, the barrier layer 136, and the gate semiconductor layer 152 may be sequentially stacked on the substrate 110. At least one of the buffer layer 120, the channel layer 132, the barrier layer 136, and the gate semiconductor layer 152 may be omitted from the semiconductor device. The buffer layer 120, the channel layer 132, the barrier layer 136, and the gate semiconductor layer 152 may be made of the same base semiconductor material, and material composition ratios of the respective layers by considering functions of the respective layers and performance of the semiconductor device.

The semiconductor device may further include a first passivation layer 161 disposed on the barrier layer 136, the gate semiconductor layer 152, and the gate electrode 155. The first passivation layer 161 may cover an upper surface of the barrier layer 136, a lateral surface of the gate semiconductor layer 152, and an upper surface and a lateral surface of the gate electrode 155. The first passivation layer 161 may contact the barrier layer 136, the gate semiconductor layer 152, and the gate electrode 155. The barrier layer 136, the gate semiconductor layer 152, and the gate electrode 155 may be protected or at least partially protected by the first passivation layer 161, and may be separated from other components. The first passivation layer 161 may include an insulating material. For example, the first passivation layer 161 may include oxide, such as SiO₂ and/or Al₂O₃. Alternatively or additionally, the first passivation layer 161 may include nitride such as SiN or oxynitride such as SiON. The first passivation layer 161 may be a single layer or a multilayer.

The source electrode 173 and the drain electrode 175 may be disposed on the channel layer 132. The source electrode 173 and the drain electrode 175 may be spaced from each other, and the gate electrode 155 and the gate semiconductor layer 152 may be disposed between the source electrode 173 and the drain electrode 175. The gate electrode 155 and the gate semiconductor layer 152 may be spaced from the source electrode 173 and the drain electrode 175. The source electrode 173 may be electrically connected to the channel layer 132 on a first side of the gate electrode 155. The drain electrode 175 may be electrically connected to the channel layer 132 on a second side of the gate electrode 155. The source electrode 173 and the drain electrode 175 may be disposed outside the drift region DTR of the channel layer 132. A boundary between the source electrode 173 and the channel layer 132 may be an edge on a first side of the drift region DTR. In a like way, a boundary between the drain electrode 175 and the channel layer 132 may be an edge on a second side of the drift region DTR. Without being limited to this, the source electrode 173 and the drain electrode 175 may not be disposed outside the drift region DTR of the channel layer 132. The channel layer 132 may not be recessed, and the source electrode 173 and the drain electrode 175 may be disposed on the upper surface of the channel layer 132. In another way, the barrier layer 136 may not be penetrated and a portion of the barrier layer 136 may be recessed so the source electrode 173 and the drain electrode 175 may be disposed on the upper surface of the barrier layer 136. Bottom surfaces of the source electrode 173 and the drain electrode 175 may contact the upper surface of the barrier layer 136. A portion of the barrier layer 136 contacting the source electrode 173 and the drain electrode 175 may be doped in high concentration. The carriers having passed through the 2-dimensional electron gas 134 may pass through the portion of the barrier layer 136 doped in high concentration, that is, the upper portion of the 2-dimensional electron gas 134 and may be transmitted to the source electrode 173 and the drain electrode 175. The source electrode 173 and the drain electrode 175 may not contact the 2-dimensional electron gas 134 in the horizontal direction. The horizontal direction may be parallel to the upper surface of the channel layer 132 or the barrier layer 136, and the source electrode 173 and the drain electrode 175 may include a conductive material. For example, the source electrode 173 and the drain electrode 175 may include one or more of a metal, a metal alloy, a conductive metal nitride, a metal silicide, a doped semiconductor material such as but not limited to doped polysilicon, a conductive metal oxide, or a conductive metal oxynitride. For example, source electrode 173 and drain electrode 175 may include one or more of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide (TiAlC—N), titanium aluminum carbide (TiAlC), titanium carbide (TiC), tantalum carbide (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, and may or may not include the same material, but are not limited thereto. The source electrode 173 and the drain electrode 175 may be a single layer or a multilayer. The source electrode 173 and the drain electrode 175 may ohmic contact the channel layer 132. A region contacting the source electrode 173 and the drain electrode 175 on the channel layer 132 may be doped in relatively higher concentration than other regions.

The source electrode 173 may include a first source electrode 173a and a second source electrode 173b. The second source electrode 173b may be disposed on the first source electrode 173a. The first source electrode 173a may directly contact the channel layer 132, and may be electrically connected to the channel layer 132. The second source electrode 173b may not directly contact the channel layer 132, and may be electrically connected to the channel layer 132 through the first source electrode 173a. The second source electrode 173b may be integrally formed with or be integral with the upper field distribution pattern 220 to be described; e.g., there may not be an interface between the second source electrode 173b and the upper field distribution pattern 220.

The drain electrode 175 may include a first drain electrode 175a and a second drain electrode 175b. The second drain electrode 175b may be disposed on the first drain electrode 175a. The first drain electrode 175a may directly contact the channel layer 132, and may be electrically connected to the channel layer 132. The second drain electrode 175b may not directly contact the channel layer 132, and may be electrically connected to the channel layer 132 through the first drain electrode 175a.

The first source electrode 173a and the first drain electrode 175a may be disposed on or in the first passivation layer 161. Trenches passing through the first passivation layer 161 and the barrier layer 136 and recessing the upper surface of the channel layer 132 may be disposed to be spaced from each other on respective sides of the gate electrode 155. A first source electrode 173a or at least a portion thereof and a first drain electrode 175a or at least a portion thereof may be disposed in the trenches disposed on respective sides of the gate electrode 155. The first source electrode 173a and the first drain electrode 175a may fill the trenches. The first source electrode 173a and the first drain electrode 175a may contact the channel layer 132 and the barrier layer 136 in the trenches. The channel layer 132 may configure a bottom surface and a side wall of the trench, and the barrier layer 136 may configure the side wall of the trench. Hence, the first source electrode 173a and the first drain electrode 175a may contact the upper surface and the lateral surface of the channel layer 132. The first source electrode 173a and the first drain electrode 175a may contact the lateral surface of the barrier layer 136. For example, the first source electrode 173a and the first drain electrode 175a may cover the lateral surfaces of the channel layer 132 and the barrier layer 136. The upper surfaces of the first source electrode 173a and the first drain electrode 175a may further protrude than the upper surface of the first passivation layer 161. The first source electrode 173a and the first drain electrode 175a may cover at least a portion of the upper surface of the first passivation layer 161. A second passivation layer 163 to be described may be disposed on the first source electrode 173a and the first drain electrode 175a. At least a portion of the first source electrode 173a and the first drain electrode 175a may be covered by the second passivation layer 163.

The second source electrode 173b and the second drain electrode 175b may be disposed on the second passivation layer 163. An opening penetrating the second passivation layer 163 may overlap the first source electrode 173a, and the second source electrode 173b may be disposed in the opening. The second source electrode 173b may fill the opening. The second source electrode 173b may contact the first source electrode 173a in the opening. The second source electrode 173b may be connected to the first source electrode 173a through the opening. Another opening penetrating the second passivation layer 163 may overlap the first drain electrode 175a, and the second drain electrode 175b may be disposed in the opening. The second drain electrode 175b may fill the opening. The second drain electrode 175b may contact the first drain electrode 175a in the opening. The second drain electrode 175b may be connected to the first drain electrode 175a through the opening. The upper surfaces of the second source electrode 173b and the second drain electrode 175b may further protrude than the upper surface of the second passivation layer 163. The second source electrode 173b and the second drain electrode 175b may cover at least a portion of the upper surface of the second passivation layer 163.

In some example embodiments, the second source electrode 173b may be connected to, e.g., may be integral with, the upper field distribution pattern 220. The second source electrode 173b and the upper field distribution pattern 220 may be integrally formed. The second source electrode 173b and the upper field distribution pattern 220 may be formed by the same process, and in some example embodiments may not have an interface therebetween.

The opening filled with the second source electrode 173b may overlap the trench filled with the first source electrode 173a. Without being limited to this, depending on cases, the opening may not overlap the trench. The opening filled with the second source electrode 173b may completely overlap the first source electrode 173a. Without being limited to this, depending on cases, at least a portion of the opening filled with the second source electrode 173b may not overlap the first source electrode 173a. The second source electrode 173b may cover the lateral surface of the first source electrode 173a, and may contact the upper surface of the first passivation layer 161. A width of the opening filled with the second source electrode 173b may be close to the width of the trench filled with the first source electrode 173a. However, a relationship between the width of the opening and the width of the trench is not limited thereto, and may be changeable in many ways.

The opening filled with the second drain electrode 175b may overlap or at least partially overlap the trench filled with the first drain electrode 175a. Without being limited to this, depending on cases, the opening may not overlap the trench. The opening filled with the second drain electrode 175b may completely overlap the first drain electrode 175a. Without being limited to this, depending on cases, at least a portion of the opening filled with the second drain electrode 175b may not overlap the first drain electrode 175a. The second drain electrode 175b may cover the lateral surface of the first drain electrode 175a, and may contact the upper surface of the first passivation layer 161. The width of the opening filled with the second drain electrode 175b may be close to the width of the trench filled with the first drain electrode 175a. The relationship between the width of the opening and the width of the trench is not limited thereto, and may be changeable in many ways.

The lower field distribution patterns 210 may be disposed between the gate electrode 155 and the drain electrode 175. The lower field distribution patterns 210 may be disposed on the first passivation layer 161. The respective lower field distribution patterns 210 may extend in the second direction D2. For example, the lower field distribution patterns 210 may extend in the same direction as the direction in which the gate electrode 155 extends.

The lower field distribution patterns 210 may be arranged to be spaced from each other in the first direction D1 on the first passivation layer 161. Referring to FIG. 1 to FIG. 3, a first lower field distribution pattern 210a, a second lower field distribution pattern 210b, and a third lower field distribution pattern 210c may be arranged to be spaced from each other sequentially in the first direction D1. FIG. 1 to FIG. 3 show three lower field distribution patterns 210, and the number of the lower field distribution patterns 210 disposed between the gate electrode 155 and the drain electrode 175 is not limited. For example, one or two lower field distribution patterns 210 may be arranged between the gate electrode 155 and the drain electrode 175. For example, four more lower field distribution patterns 210 may be arranged between the gate electrode 155 and the drain electrode 175.

In some example embodiments, the respective lower field distribution patterns 210 may float, or may float during operation of the semiconductor device. The lower field distribution patterns 210 may be electrically insulated. For example, the respective lower field distribution patterns 210 may be surrounded by the first passivation layer 161 and the second passivation layer 163 to be described. Referring to FIG. 2 and FIG. 3, the respective lower surfaces of the lower field distribution pattern 210 may contact the upper surface of the first passivation layer 161. The lateral surface and the upper surface of the lower field distribution pattern 210 may contact the second passivation layer 163.

In some example embodiments, the respective lower field distribution patterns 210 may be spaced from the upper field distribution pattern 220. The respective lower field distribution patterns 210 may be spaced from the upper field distribution pattern 220 in the third direction D3. The second passivation layer 163 may be disposed between the lower field distribution pattern 210 and the upper field distribution pattern 220. A region such as at least a predetermined region of the respective lower field distribution patterns 210 may overlap or at least partially overlap the upper field distribution pattern 220 in the third direction D3.

The lower field distribution patterns 210 may include a conductive material. For example, the lower field distribution patterns 210 may include one or more of a metal, a metal alloy, a conductive metal nitride, a metal silicide, a doped semiconductor material such as but not limited to doped polysilicon, a conductive metal oxide, or a conductive metal oxynitride. For example, the lower field distribution patterns 210 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide (TiAlC—N), titanium aluminum carbide (TiAlC), titanium carbide (TiC), tantalum carbide (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The lower field distribution patterns 210 may be a single layer or a multilayer. In some example embodiments, the lower field distribution patterns 210 may include the same material as the source electrode 173 and/or the drain electrode 175. In some example embodiments, the lower field distribution patterns 210 may be formed by the same process as the source electrode 173 and/or the drain electrode 175.

The semiconductor device may further include a second passivation layer 163 disposed on the first source electrode 173a, the first drain electrode 175a, the first passivation layer 161, and the lower field distribution patterns 210. The second passivation layer 163 may cover the upper surface of the first passivation layer 161. The second passivation layer 163 may cover at least a portion of the lateral surfaces and the upper surfaces of the first source electrode 173a and the first drain electrode 175a. In detail, the second passivation layer 163 may cover a predetermined region of the lateral surface and the upper surface of the first source electrode 173a protruding from the upper surface of the first passivation layer 161. The second passivation layer 163 may cover the lateral surface and the upper surface of the first drain electrode 175a protruding from the upper surface of the first passivation layer 161. The second passivation layer 163 may surround regions such as predetermined regions of the second source electrode 173b and the second drain electrode 175b filling the respective openings.

In some example embodiments, the second passivation layer 163 may cover the lower field distribution patterns 210. The upper surfaces and the lateral surfaces of the respective lower field distribution patterns 210 may be surrounded by the second passivation layer 163. The lower field distribution pattern 210 may be separated from other components by the first passivation layer 161 and the second passivation layer 163.

The second passivation layer 163 may include an insulating material. For example, the second passivation layer 163 may include oxide, such as SiO₂ or Al₂O₃. For another example, the second passivation layer 163 may include one or more of a nitride such as SiN or oxynitride such as SiON. The second passivation layer 163 may be a single layer or a multilayer. In some example embodiments, the second passivation layer 163 may include the same material as the first passivation layer 161. In this case, differing from what are shown in FIG. 1 to FIG. 3, the boundary or interface between the first passivation layer 161 and the second passivation layer 163 may not be seen.

The upper field distribution pattern 220 may be disposed on the gate electrode 155 and the lower field distribution patterns 210. The upper field distribution pattern 220 may be disposed between the source electrode 173 and the drain electrode 175. The upper field distribution pattern 220 may be spaced from the lower field distribution patterns 210. The upper field distribution pattern 220 may be spaced from the lower field distribution patterns 210 in the third direction D3.

The second passivation layer 163 may be disposed between the upper field distribution pattern 220 and the lower field distribution patterns 210. The upper field distribution pattern 220 may be spaced from the lower field distribution patterns 210 in the third direction D3 by the second passivation layer 163. The upper field distribution pattern 220 may cover at least a predetermined region of the upper surface of the second passivation layer 163. A region such as at least a predetermined region of the upper field distribution pattern 220 may overlap the source electrode 173 in the third direction D3. The upper field distribution pattern 220 may be electrically connected to the source electrode 173. The upper field distribution pattern 220 may be integrally formed with the second source electrode 173b. The upper field distribution pattern 220 may be connected to the first source electrode 173a through the second source electrode 173b. Referring to FIG. 1 to FIG. 3, the upper field distribution pattern 220 may pass through a region such as a predetermined region of the second passivation layer 163 and may be connected to the first source electrode 173a contacting the upper surface of the second source electrode 173b, and the upper field distribution pattern 220 may be connected to the upper surface of the first source electrode 173a. As shown in FIG. 1 to FIG. 3, when the source electrode 173 and the upper field distribution pattern 220 are integrally formed, the boundary between the source electrode 173 and the upper field distribution pattern 220 may not be seen.

In some example embodiments, an end disposed near the drain electrode 175 of the upper field distribution pattern 220 may be disposed between the lower field distribution pattern 210 and the drain electrode 175. The upper field distribution pattern 220 may overlap the lower field distribution patterns 210 in the third direction D3. In some example embodiments, the upper field distribution pattern 220 may completely cover the lower field distribution patterns 210.

The upper field distribution pattern 220 may include a conductive material. For example, the upper field distribution pattern 220 may include the same material as the source electrode 173. Without being limited to this, upper field distribution pattern 220 may include a material that is different from the source electrode 173. For example, the upper field distribution pattern 220 may include one or more of a metal, a metal alloy, a conductive metal nitride, a metal silicide, a doped semiconductor material, a conductive metal oxide, or a conductive metal oxynitride. For example, the upper field distribution pattern 220 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide (TiAlC—N), titanium aluminum carbide (TiAlC), titanium carbide (TiC), tantalum carbide (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The upper field distribution pattern 220 may be a single layer or a multilayer.

In some example embodiments, the upper field distribution pattern 220 and the lower field distribution pattern 210 may disperse an electric field focused around the gate electrode 155. When a high voltage is applied to the drain electrode 175 in the gate Off state, the electric field may be focused around the gate electrode 155. Particularly, the electric field may be focused on one side disposed near the drain electrode 175 of the gate electrode 155. When the electric field is focused on the gate electrode 155, a leakage current may increase and a breakdown voltage may reduce.

The semiconductor device may include lower field distribution patterns 210 disposed between the gate electrode 155 and the drain electrode 175 and in a floating state, and an upper field distribution pattern 220 spaced from the lower field distribution patterns 210 thereon. According to some example embodiments, when a high voltage is applied to the drain electrode 175 in the gate Off state, the electric field may be generated between the lower field distribution patterns 210 and the upper field distribution pattern 220 according to a coupling effect. In this case, the electric field may not be focused around the gate electrode 155 but may be dispersed in the direction of the lower field distribution patterns 210 and the upper field distribution pattern 220, and hence, the leakage current of the semiconductor device may be reduced and the breakdown voltage may be increased.

The semiconductor device may further include a third passivation layer 165 disposed on the second passivation layer 163. The third passivation layer 165 may protect the upper field distribution pattern 220 from the outside. The third passivation layer 165 may cover the upper surface of the second passivation layer 163, and the upper surface and the lateral surface of the upper field distribution pattern 220.

The third passivation layer 165 may include an insulating material. For example, the third passivation layer 165 may include oxide such as SiO₂ and/or Al₂O₃. Alternatively or additionally, the third passivation layer 165 may include nitride such as SiNx and/or oxynitride such as SiON. The third passivation layer 165 may be a single layer or a multilayer. The third passivation layer 165 may include the same insulating material as the second passivation layer 163. In this case, the boundary between the second passivation layer 163 and the third passivation layer 165 may not be seen at the portion where the second passivation layer 163 contacts the third passivation layer 165.

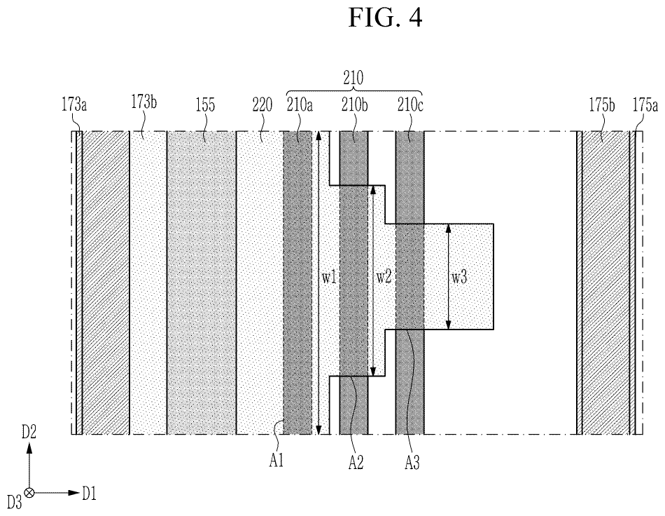

FIG. 4 shows a top plan view of a semiconductor device according to some example embodiments. The semiconductor device shown in FIG. 4 mostly corresponds to the above-described example embodiments so differences from the same will be mainly described. The semiconductor device shown in FIG. 4 may be partly different from the above-noted example embodiments in that the areas in which the lower field distribution patterns 210 overlap the upper field distribution pattern 220 are different from each other.

In some example embodiments, the width of the upper field distribution pattern 220 in the second direction D2 may not be constant. Referring to FIG. 4, the upper field distribution pattern 220 may have a first width w1 in the region in which the upper field distribution pattern 220 overlaps the first lower field distribution pattern 210a. The upper field distribution pattern 220 may have a second width w2 that is less than the first width w1 in the region in which the upper field distribution pattern 220 overlaps the second lower field distribution pattern 210b. The upper field distribution pattern 220 may have a third width w3 that is less than the second width w2 in the region in which the upper field distribution pattern 220 overlaps the third lower field distribution pattern 210c. FIG. 4 shows that the upper field distribution pattern 220 has a planar shape in which the width with respect to the second direction D2 is reduced stepwise when proceeding in the first direction D1, and the shape of the upper field distribution pattern 220 is not limited thereto. For example, the upper field distribution pattern 220 may have a planar trapezoidal or triangular shape in which the width with respect to the second direction D2 is linearly reduced in the first direction D1.

Differing from what is shown in FIG. 4, the upper field distribution pattern 220 may have a planar shape in which the width with respect to the second direction D2 is increased stepwise when proceeding in the first direction D1. In another way, the upper field distribution pattern 220 may have a planar trapezoidal shape in which the width with respect to the second direction D2 is linearly increased when proceeding in the first direction D1.

As the width of the upper field distribution pattern 220 in the second direction D2 is gradually reduced, the areas in which the first lower field distribution pattern 210a, the second lower field distribution pattern 210b, and the third lower field distribution pattern 210c overlap the upper field distribution pattern 220 in the third direction D3 may be different.

Referring to FIG. 4, the first lower field distribution pattern 210a may overlap or at least partially overlap the upper field distribution pattern 220 in the third direction D3 by a first area A1. In detail, the first lower field distribution pattern 210a may entirely overlap the upper field distribution pattern 220. The upper field distribution pattern 220 may cover the entire upper surface of the first lower field distribution pattern 210a.

A region such as a predetermined region of the second lower field distribution pattern 210b and the third lower field distribution pattern 210c may overlap the upper field distribution pattern 220 in the third direction D3. The second lower field distribution pattern 210b may overlap the upper field distribution pattern 220 in the third direction D3 by a second area A2 that is less than the first area A1. The third lower field distribution pattern 210c may overlap the upper field distribution pattern 220 in the third direction D3 by a third area A3 that is less than the second area A2.

The size of the electric field generated between the upper field distribution pattern 220 and the lower field distribution pattern 210 may become different according to the size of the area in which the upper field distribution pattern 220 overlaps the lower field distribution pattern 210. For example, the size of the electric field generated between the upper field distribution pattern 220 and the lower field distribution pattern 210 may have a greater value when the area in which the upper field distribution pattern 220 overlaps the lower field distribution pattern 210 increases. In this case, in some example embodiments shown in FIG. 4, the size of the electric field between the lower field distribution patterns 210 and the upper field distribution pattern 220 may be reduced when approaching the drain electrode 175.

In some example embodiments shown in FIG. 4, the area in which the upper field distribution pattern 220 overlaps the lower field distribution patterns 210 is gradually reduced in accordance with a distance from the gate electrode 155 in the first direction D1, and the shape of the upper field distribution pattern 220 is not limited thereto. The upper field distribution pattern 220 may be designed to have various shapes by considering the region where the electric field is focused in the semiconductor device with various structures, the leakage current, individual structures of respective components included in the semiconductor device, and materials included in the respective components.

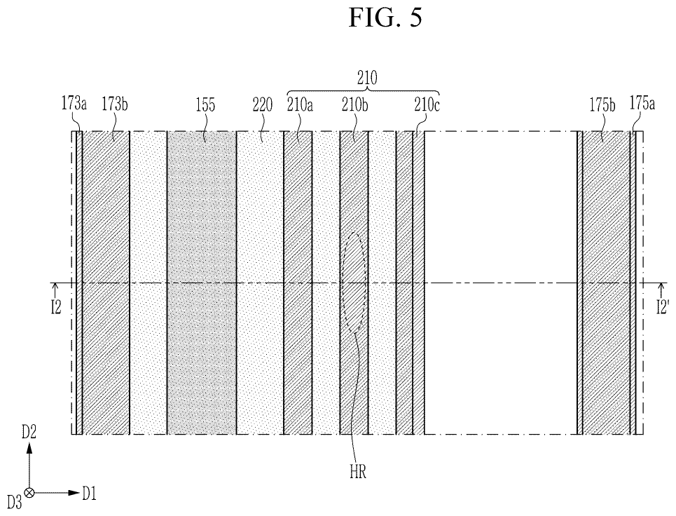

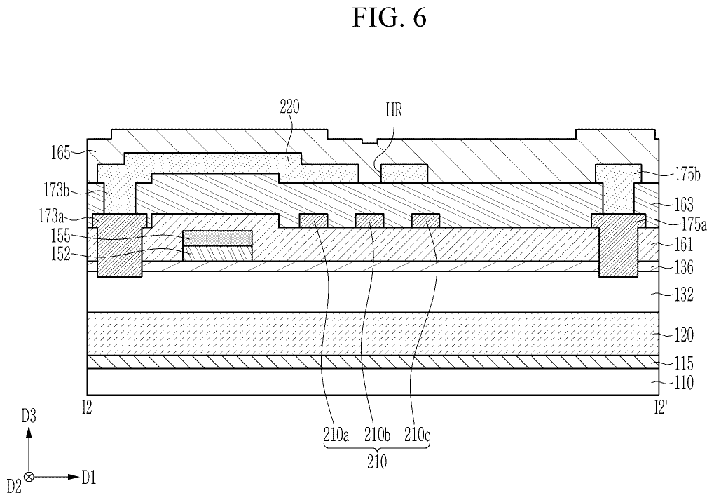

FIG. 5 and FIG. 6 show a semiconductor device according to some example embodiments. In detail, FIG. 5 shows a top plan view of a semiconductor device according to some example embodiments. FIG. 6 shows a cross-sectional view of a semiconductor device with respect to a line I2-I2′ of FIG. 5 according to some example embodiments. The semiconductor device shown in FIG. 5 and FIG. 6 mostly corresponds to the above-described embodiments so differences from the same will be mainly described. The semiconductor device shown in FIG. 5 and FIG. 6 may be partly different from the above-noted embodiments in that the upper field distribution pattern 220 includes a hole region HR, and the upper field distribution pattern 220 does not cover the entire third lower field distribution pattern 210c.

Referring to FIG. 5 and FIG. 6, the semiconductor device may further include a hole region HR penetrating the upper field distribution pattern 220 in the third direction D3. The hole region HR may be filled by the third passivation layer 165. Referring to FIG. 5, the hole region HR has an oval planar shape, and without being limited thereto, the hole region HR may have various types of planar shapes. For example, the hole region HR may have polygonal planar shapes such as a triangle or a quadrangle. FIG. 5 and FIG. 6 show one hole region HR, and the number of the hole regions HR is not limited.

The area in which the upper field distribution pattern 220 overlaps the lower field distribution pattern 210 may be adjusted by forming the hole region HR penetrating the upper field distribution pattern 220. FIG. 5 and FIG. 6 show that the hole region HR is disposed on the second lower field distribution pattern 210b, and the number of the hole regions HR and the formed positions thereof may be designed in various ways by considering the region in which the electric field is focused in the semiconductor device. For example, the hole region HR may be disposed on the first lower field distribution pattern 210a, or may be disposed on the third lower field distribution pattern 210c. For example, at least one hole region HR may be disposed on two or more of the lower field distribution patterns 210a, 210b, and 210c. For another example, hole regions BR may be disposed on at least one of the first lower field distribution pattern 210a, the second lower field distribution pattern 210b, and the third lower field distribution pattern 210c. A number of lower field distribution patterns 210 is not limited to three, and may be more or less than three.

In some example embodiments, the upper field distribution pattern 220 may not cover the entire region of the third lower field distribution pattern 210c. Referring to FIG. 5 and FIG. 6, an end disposed near the drain electrode 175 of the upper field distribution pattern 220 may be disposed on the third lower field distribution pattern 210c. A length for the upper field distribution pattern 220 to extend to the direction of the drain electrode 175 in the first direction D1 may be shorter, compared to the previous embodiments. Hence, the upper field distribution pattern 220 may extend in the first direction D1 to cover a region such as a region such as a predetermined region of the upper surface of the third lower field distribution pattern 210c. According to some example embodiments, the area in which the lower field distribution pattern 210 disposed the nearest the drain electrode 175 overlaps the upper field distribution pattern 220 may be controlled by adjusting the upper field distribution pattern 220 extending in the first direction D1.

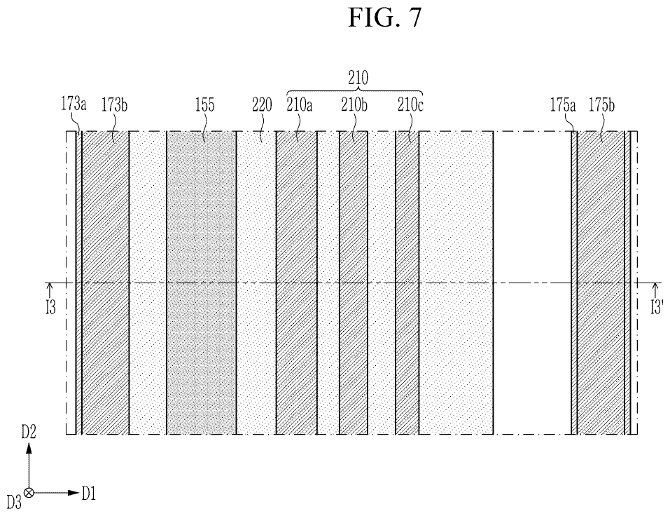

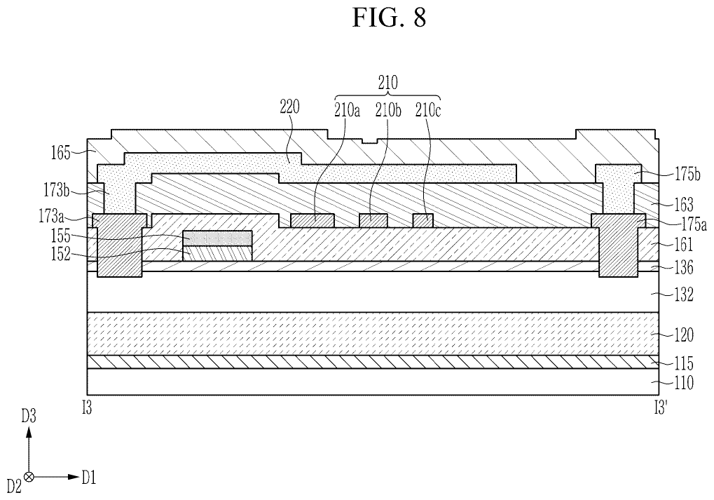

FIG. 7 and FIG. 8 show a semiconductor device according to some example embodiments. In detail, FIG. 7 shows a top plan view of a semiconductor device according to some example embodiments. FIG. 8 shows a cross-sectional view of a semiconductor device with respect to a line I3-I3′ of FIG. 7 according to some example embodiments. The semiconductor device shown in FIG. 7 and FIG. 8 mostly corresponds to the above-described example embodiments so differences from the same will be mainly described. Regarding the semiconductor device shown in FIG. 7 and FIG. 8, the width of the lower field distribution patterns 210 may be partly different from the above-noted embodiments.

In the semiconductor device, the respective widths of the lower field distribution patterns 210 may be different from each other. Referring to FIG. 7 and FIG. 8, the widths of the first lower field distribution pattern 210a, the second lower field distribution pattern 210b, and the third lower field distribution pattern 210c in the first direction D1 may be different from each other. In detail, the width of the second lower field distribution pattern 210b in the first direction D1 may be less than the width of the first lower field distribution pattern 210a in the first direction D1. The width of the third lower field distribution pattern 210c in the first direction D1 may be less than the width of the second lower field distribution pattern 210b in the first direction D1. Therefore, the area in which the first lower field distribution pattern 210a overlaps the upper field distribution pattern 220, the area in which the second lower field distribution pattern 210b overlaps the upper field distribution pattern 220, and the area in which the third lower field distribution pattern 210c overlaps the upper field distribution pattern 220 may be different.

Differing from what are shown in FIG. 7 and FIG. 8, the widths of two of the lower field distribution patterns 210a, 210b, and 210c in the first direction D1 may be the same as or close to each other, and the width of the rest in the first direction D1 may be different from them.

Referring to FIG. 7 and FIG. 8, the widths of the lower field distribution patterns 210 in the first direction D1 are shown to be gradually reduced in accordance with a distance to the drain electrode 175, and the widths of the lower field distribution patterns 210 in the first direction D1 are not limited by the embodiment described with reference to FIG. 7 and FIG. 8. For example, the widths of the lower field distribution patterns 210 in the first direction D1 may be designed in many ways by considering the region in which the electric field is focused in the semiconductor device.

The area in which the lower field distribution patterns 210 overlap the upper field distribution pattern 220 in the third direction D3 may be controlled by adjusting the widths of the lower field distribution patterns 210 in the first direction D1.

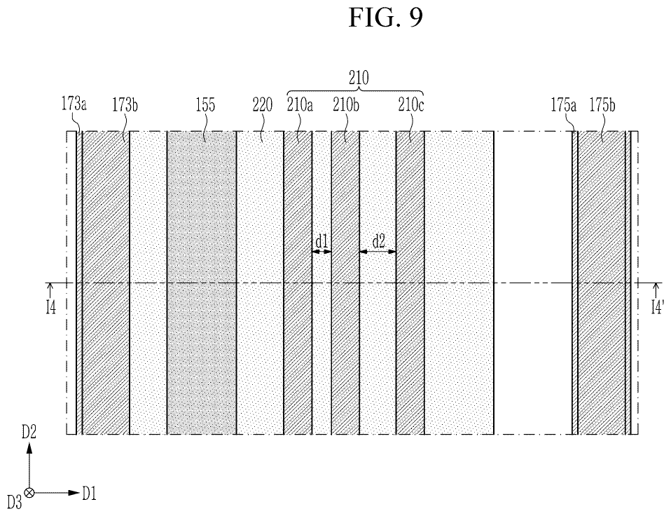

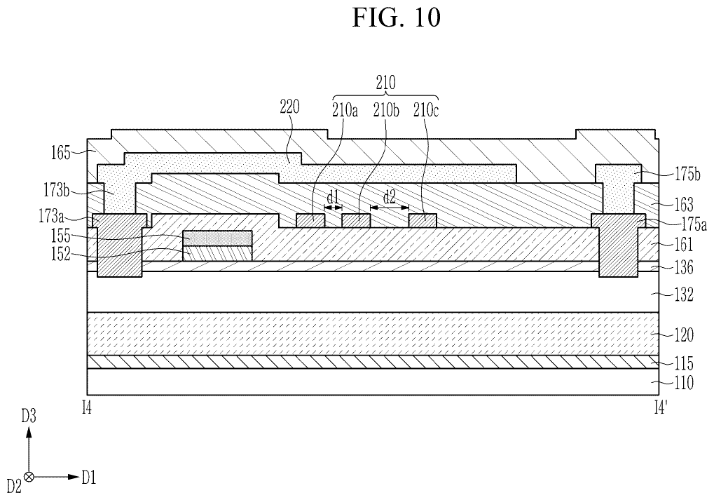

FIG. 9 and FIG. 10 show a semiconductor device according to some example embodiments. In detail, FIG. 9 shows a top plan view of a semiconductor device according to some example embodiments. FIG. 10 shows a cross-sectional view of a semiconductor device with respect to a line I4-I4′ of FIG. 9 according to some example embodiments. The semiconductor device shown in FIG. 9 and FIG. 10 mostly corresponds to the above-described embodiments so differences from the same will be mainly described. Regarding the semiconductor device shown in FIG. 9 and FIG. 10, the distances between the lower field distribution patterns 210 may be partly different from the above-noted example embodiments according to a comparison.

In some example embodiments, the distances between the two adjacent lower field distribution patterns 210 may be different from each other. In detail, referring to FIG. 9 and FIG. 10, the distance d1 between the first lower field distribution pattern 210a and the second lower field distribution pattern 210b may be less than the distance d2 between the second lower field distribution pattern 210b and the third lower field distribution pattern 210c. However, without being limited thereto, differing from what is shown, the distance d1 between the first lower field distribution pattern 210a and the second lower field distribution pattern 210b may be greater than the distance d2 between the second lower field distribution pattern 210b and the third lower field distribution pattern 210c.

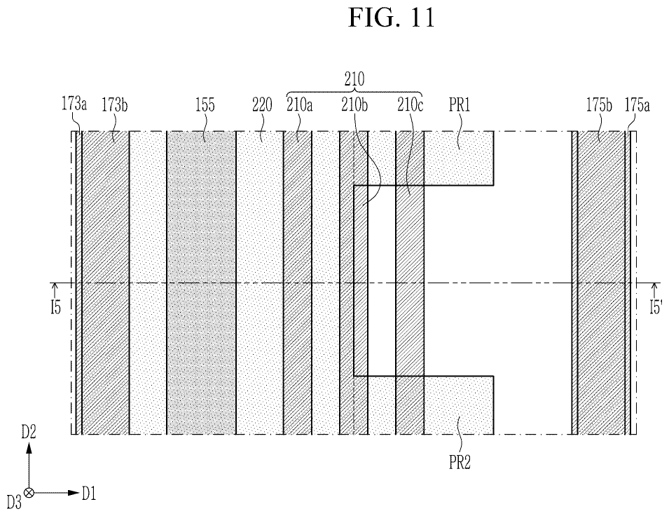

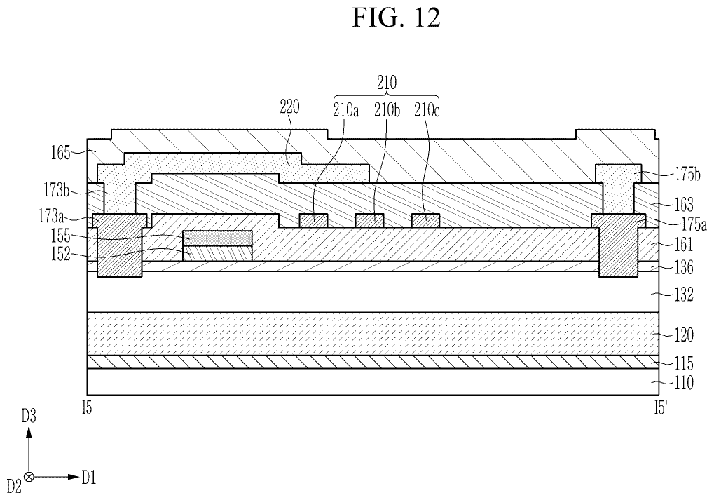

FIG. 11 and FIG. 12 show a semiconductor device according to some example embodiments. In detail, FIG. 11 shows a top plan view of a semiconductor device according to some example embodiments. FIG. 12 shows a cross-sectional view of a semiconductor device with respect to a line I5-I5′ of FIG. 11 to some example embodiments. The semiconductor device shown in FIG. 11 and FIG. 12 mostly corresponds to the above-described embodiments so differences from the same will be mainly described. The semiconductor device shown in FIG. 11 and FIG. 12 may be partly different from the above-noted embodiments in that the semiconductor device includes protruding regions PR1 and PR2 protruding in the first direction D1 from an end of the upper field distribution pattern 220.

Referring to FIG. 11 and FIG. 12, the upper field distribution pattern 220 may extend toward the drain electrode 175 from the source electrode 173 in the first direction D1. The upper field distribution pattern 220 may pass through the first lower field distribution pattern 210a and may extend on the second lower field distribution pattern 210b. The upper field distribution pattern 220 may extend in the first direction D1 to cover a region such as a predetermined region of the upper surface of the third lower field distribution pattern 210c. Hence, an end of the upper field distribution pattern 220 disposed near the drain electrode 175 may be disposed on the second lower field distribution pattern 210b.

In some example embodiments, the upper field distribution pattern 220 may overlap the first lower field distribution pattern 210a in the third direction D3. In some example embodiments, the upper field distribution pattern 220 may overlap a region such as a predetermined region of the second lower field distribution pattern 210b in the third direction D3. The upper field distribution pattern 220 may not overlap the third lower field distribution pattern 210c.

The semiconductor device may include a first protruding region PR1 and second protruding region PR2 protruding in the first direction D1 from an end of the upper field distribution pattern 220 disposed near the drain electrode 175. Referring to FIG. 11, the first protruding region PR1 and the second protruding region PR2 may pass over the second lower field distribution pattern 210b and the third lower field distribution pattern 210c and may extend toward the drain electrode 175. Ends of the first protruding region PR1 and the second protruding region PR2 disposed near the drain electrode 175 may be disposed between the third lower field distribution pattern 210c and the drain electrode 175. Hence, the first protruding region PR1 and the second protruding region PR2 may overlap a region such as a predetermined region of the second lower field distribution pattern 210b and the third lower field distribution pattern 210c in the third direction D3.

In some example embodiments, the first protruding region PR1 and the second protruding region PR2 may be integrally formed with the upper field distribution pattern 220. In this case, the boundary between the first protruding region PR1 and the second protruding region PR2, and the upper field distribution pattern 220 may not be seen.

FIG. 11 shows that the first protruding region PR1 is disposed along an upper corner in a plan view, and the second protruding region PR2 is disposed along a lower corner, and the positions where the first protruding region PR1 and the second protruding region PR2 protrude from ends of the upper field distribution pattern 220 are not limited by the embodiment shown in FIG. 11. For example, the first protruding region PR1 may be spaced from the upper corner of the plan view of FIG. 11 in an opposite direction to the second direction D2 by a gap such as a predetermined gap. In some example embodiments, the second protruding region PR2 may be spaced from a lower corner of the plan view of FIG. 11 in the second direction D2 by a predetermined gap.

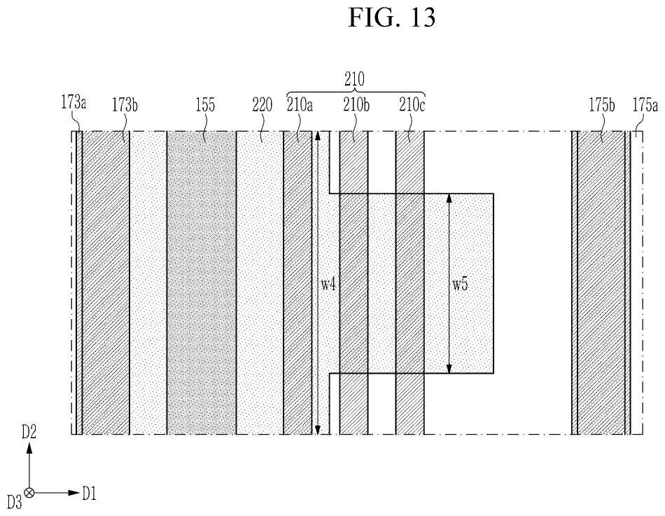

FIG. 13 shows a semiconductor device according to some example embodiments. The semiconductor device shown in FIG. 13 mostly corresponds to the above-described embodiments so differences from the same will be mainly described. Regarding the semiconductor device shown in FIG. 13, the width of the upper field distribution pattern 220 in the second direction D2 may be partly different from the above-noted embodiments.

In some example embodiments, the width of the upper field distribution pattern 220 in the second direction D2 may not be constant. Referring to FIG. 13, the upper field distribution pattern 220 may have a fourth width w4 in the region in which the upper field distribution pattern 220 overlaps the first lower field distribution pattern 210a. The upper field distribution pattern 220 may have a fifth width w5 that is less than the fourth width w4 in the region in which the upper field distribution pattern 220 overlaps the second lower field distribution pattern 210b and the third lower field distribution pattern 210c. In some example embodiments, the boundary of the region of the upper field distribution pattern 220 with the fourth width w4 and the region of the upper field distribution pattern 220 with the fifth width w5 may be disposed between the first lower field distribution pattern 210a and the second lower field distribution pattern 210b.

The area in which the first lower field distribution pattern 210a overlaps the upper field distribution pattern 220 in the third direction D3 may be greater than the area in which the second lower field distribution pattern 210b and the third lower field distribution pattern 210c overlap the upper field distribution pattern 220 in the third direction D3. In some example embodiments, the upper field distribution pattern 220 may cover the entire first lower field distribution pattern 210a. In some example embodiments, the upper field distribution pattern 220 may cover a region such as a predetermined region of the second lower field distribution pattern 210b and the third lower field distribution pattern 210c.

Differing from what is shown in FIG. 13, the boundary of the region of the upper field distribution pattern 220 with the fourth width w4 and the region of the upper field distribution pattern 220 with the fifth width w5 may be disposed between the second lower field distribution pattern 210b and the third lower field distribution pattern 210c. The area in which the first lower field distribution pattern 210a and the second lower field distribution pattern 210b overlap the upper field distribution pattern 220 in the third direction D3 may be greater than the area in which the third lower field distribution pattern 210c overlaps the upper field distribution pattern 220 in the third direction D3. In this case, the upper field distribution pattern 220 may cover the entire first lower field distribution pattern 210a and the second lower field distribution pattern 210b. The upper field distribution pattern 220 may cover a region such as a predetermined region of the third lower field distribution pattern 210c.

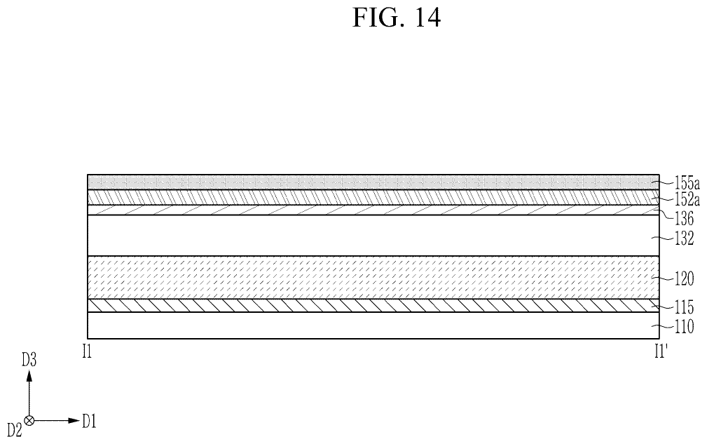

FIG. 14 to FIG. 22 show cross-sectional views of a process for manufacturing a semiconductor device in process order according to some example embodiments.

As shown in FIG. 14, a seed layer 115, a buffer layer 120, a channel layer 132, a barrier layer 136, and a gate semiconductor material layer 152a may be sequentially formed on the substrate 110. In some example embodiments, the seed layer 115, the buffer layer 120, the channel layer 132, the barrier layer 1366, and the gate semiconductor material layer 152a may be formed, for example, with one or more of a chemical vapor deposition (CVD) process and/or an atomic layer deposition (ALD) process; example embodiments are not limited thereto.

The substrate 110 may include a semiconductor material. For example, the substrate 110 may include sapphire, Si, SiC, AlN, GaN, or combinations thereof. The substrate 110 may be a silicon on insulator (SOI) substrate. However, the material of the substrate 110 is not limited thereto, and generally-used substrates may be applied.

A seed layer 115 may be formed on the substrate 110. In the final structure of the semiconductor device, the seed layer 115 may be disposed between the substrate 110 and the buffer layer 120. The seed layer 115 may function as a seed for growing the buffer layer 120, and may be made of a crystal lattice structure that becomes the seed of the buffer layer 120.

The buffer layer 120, the channel layer 132, the barrier layer 136, and the gate semiconductor material layer 152a may be sequentially formed by using an epitaxial growth method such as a heterogenous epitaxial growth process. The buffer layer 120 may be formed on the substrate 110, the high resistance layer 126 and the channel layer 132 may be formed on the buffer layer 120, the barrier layer 136 may be formed on the channel layer 132, and the gate semiconductor material layer 152a may be formed on the barrier layer 136.

The buffer layer 120, the channel layer 132, the barrier layer 136, and the gate semiconductor material layer 152a may be made of the same-based semiconductor material. However, material composition ratios of the respective layers may be different by considering the functions of the respective layers and performance of the semiconductor device. The buffer layer 120, the channel layer 132, the barrier layer 136, and the gate semiconductor material layer 152a may include one or more materials selected from the Group III-V materials, for example, nitrides containing Al, Ga, In, B, or combinations thereof. The buffer layer 120, the channel layer 132, the barrier layer 136, and the gate semiconductor material layer 152a may be AlₓIn_{y}Ga_{1-x-y}N (0≤x≤1, 0≤y≤1, x+y≤1). For example, the buffer layer 120, the channel layer 132, the barrier layer 136, and the gate semiconductor material layer 152a may include at least one of AlN, GaN, InN, InGaN, AlGaN, AlInN, and AlInGaN. The barrier layer 136 may include a material with a different energy band gap from the channel layer 132. The barrier layer 136 may have a higher energy band gap than the channel layer 132. The gate semiconductor material layer 152a may include a material with a different energy band gap from the barrier layer 136.

For example, the substrate 110 may include Si, the buffer layer 120 may include GaN, the high resistance layer 126 may include GaN, the channel layer 132 may include GaN, and the barrier layer 136 may include AlGaN. Impurities may/may not be doped to the channel layer 132 and the barrier layer 136. The gate semiconductor material layer 152a may include GaN, and may be doped with the impurities. The gate semiconductor material layer 152a may be doped with a p-type impurity, for example magnesium (Mg).

The gate electrode material layer 155a may be formed on the gate semiconductor material layer 152a. The gate semiconductor material layer 152a is disposed between the barrier layer 136 and the gate electrode material layer 155a.

The gate electrode material layer 155a may be formed using a deposition process. For example, the gate electrode material layer 155a may be formed using at least one of electron beam deposition (E-beam evaporation), sputtering, physical vapor deposition (PVD), thermal chemical vapor deposition (thermal CVD), low-pressure chemical vapor deposition (LP-CVD), plasma enhanced chemical vapor deposition (PE-CVD), and atomic layer deposition (ALD), but is not limited thereto.

The gate electrode material layer 155a may include a conductive material. For example, the gate electrode material layer 155a may include a metal, a metal alloy, a conductive metal nitride, a metal silicide, a doped semiconductor material, a conductive metal oxide, or a conductive metal oxynitride. For example, the gate electrode material layer 155a may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide (TiAlC—N), titanium aluminum carbide (TiAlC), titanium carbide (TiC), tantalum carbide (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The gate electrode material layer 155a may be a single layer or a multilayer.

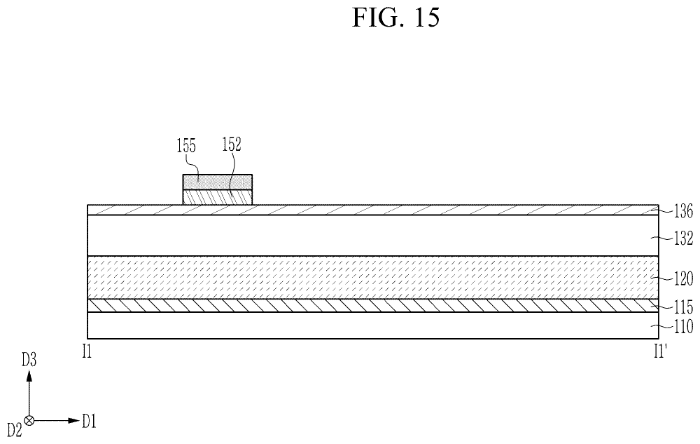

The gate electrode 155 and the gate semiconductor layer 152 may be formed, as shown in FIG. 15, by patterning the gate electrode material layer 155a and the gate semiconductor material layer 152a using a photo and etching process.

For example, a hard mask layer, such as a nitride and/or oxide hardmask layer, and a photoresist layer may be sequentially formed on the gate electrode material layer 155a. A photoresist pattern may be formed by patterning the photoresist layer using a photo process. The hard mask pattern may be formed by etching the hard mask layer by using the photoresist pattern as a mask. At least a portion of the gate electrode material layer 155a and the gate semiconductor material layer 152a may be removed by continuously etching the gate electrode material layer 155a and the gate semiconductor material layer 152a using the hard mask pattern as a mask. Hence, the rest of the gate electrode material layer 155a may become the gate electrode 155. The rest of the gate semiconductor material layer 152a may become the gate semiconductor layer 152. The gate semiconductor layer 152 may be disposed between the barrier layer 136 and the gate electrode 155. The gate electrode 155 may Schottky-contact or ohmic-contact the gate semiconductor layer 152.

The gate semiconductor layer 152 and the gate electrode 155 may have the same pattern by patterning the gate semiconductor material layer 152a and the gate electrode material layer 155a using the same mask. That is, the gate semiconductor layer 152 and the gate electrode 155 may have the same planar shape. The gate semiconductor layer 152 and the gate electrode 155 may have the same width in a cross-sectional view. The gate semiconductor layer 152 may completely overlap the gate electrode 155 in a perpendicular direction, and the upper surface of the gate semiconductor layer 152 may be generally covered by the gate electrode 155.

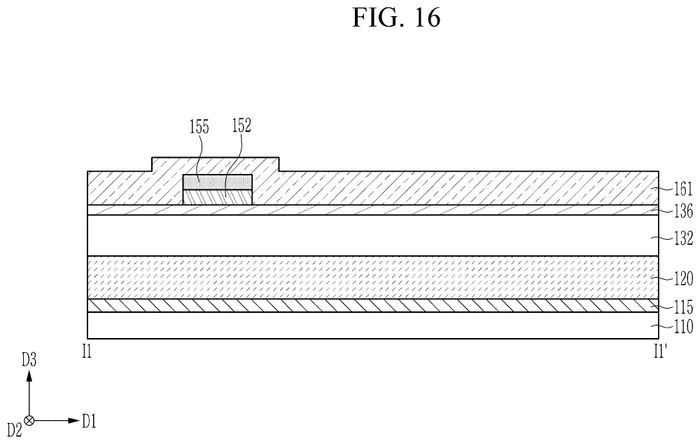

As shown in FIG. 16, a first passivation layer 161 may be formed on the barrier layer 136 and the gate electrode 155.

The first passivation layer 161 may be formed by the deposition process. The first passivation layer 161 may include an insulating material. For example, the first passivation layer 161 may include a material such as SiO₂, SiN, SiON, or Al₂O₃. The first passivation layer 161 is shown as a single layer, and depending on cases, it may be a multilayer. The first passivation layer 161 may be formed by sequentially depositing different materials. Alternatively, the first passivation layer 161 made of layers with different characteristics may be formed by changing deposition conditions using the same material. Particularly, a portion of the first passivation layer 161 disposed near the barrier layer 136 may be made of an insulating material with much better quality than other portions. This is to prevent or reduce electrons forming a channel from being trapped in the channel layer 132 disposed on a power portion of the barrier layer 136. A portion of the first passivation layer 161 contacting the barrier layer 136 may be made of SiO₂.

The lateral surfaces of the gate electrode 155 and the gate semiconductor layer 152 may be covered by the first passivation layer 161. The lateral surfaces of the gate electrode 155 and the gate semiconductor layer 152 may contact the first passivation layer 161. A step may be generated between the portion of the first passivation layer 161 overlapping the gate electrode 155 and the gate semiconductor layer 152 and the rest thereof. Without being limited to this, depending on cases, the upper surface of the first passivation layer 161 may be planar. For example, when the first passivation layer 161 is formed to be relatively thick, no step may be generated between the portion of the first passivation layer 161 overlapping the gate electrode 155 and the gate semiconductor layer 152 and the rest thereof.

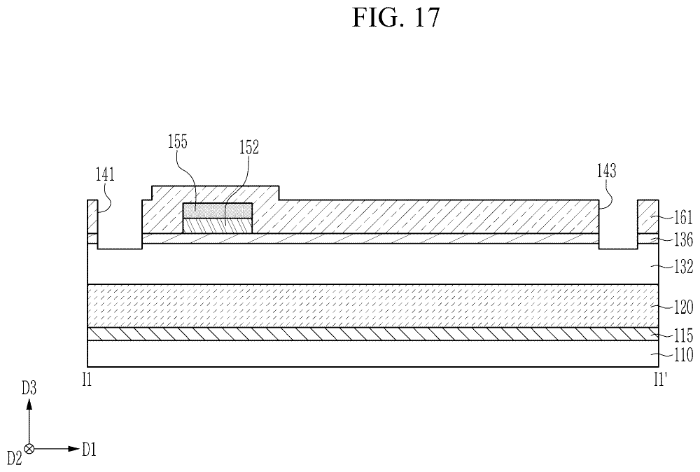

As shown in FIG. 17, a first trench 141 and a second trench 143 may be formed by patterning the first passivation layer 161 using a photo and etching process. The barrier layer 136 and the channel layer 132 may be patterned together in addition to the first passivation layer 161.

For example, a photoresist pattern may be formed on the first passivation layer 161, and the first passivation layer 161, the barrier layer 136, and the channel layer 132 may be sequentially etched by using the same as a mask. By the first trench 141 and second trench 143, the first passivation layer 161 and the barrier layer 136 may be penetrated, and the upper surface of the channel layer 132 may be recessed. The channel layer 132 may not be penetrated by the first trench 141 or the second trench 143. That is, a depth by which the upper surface of the channel layer 132 is recessed may be less than the thickness of the channel layer 132. Here, the depth by which the upper surface of the channel layer 132 is recessed may be much less than the thickness of the channel layer 132. For example, the depth by which the upper surface of the channel layer 132 is recessed may be about 0% to about 30% of the thickness of the channel layer 132. The depth by which the upper surface of the channel layer 132 is recessed may be less than the thickness of the barrier layer 136. Without being limited to this, the depth by which the upper surface of the channel layer 132 is recessed may be changeable in many ways. By the first trench 141 and the second trench 143, the lateral surfaces of the first passivation layer 161 and the barrier layer 136 may be exposed, and the upper surface and the lateral surface of the channel layer 132 may be exposed. The channel layer 132 may form a bottom surface and a side wall of the first trench 141 and the second trench 143, and the barrier layer 136 may form a side wall of the first trench 141 and the second trench 143.

The first trench 141 may be spaced from the second trench 143. The first trench 141 and the second trench 143 may be disposed on respective sides of the gate electrode 155. The first trench 141 may be disposed on one side of the gate electrode 155 to be spaced from the gate electrode 155. The second trench 143 may be disposed on another side of the gate electrode 155 to be spaced from the gate electrode 155. The distance for the first trench 141 to be spaced from the gate electrode 155 may be less than the distance for the second trench 143 to be spaced from the gate electrode 155. The shapes of the first trench 141 and the second trench 143 such as widths or depths are shown to be similar to each other, but are not limited thereto. The shapes of the first trench 141 and the second trench 143 may be changeable in many ways.

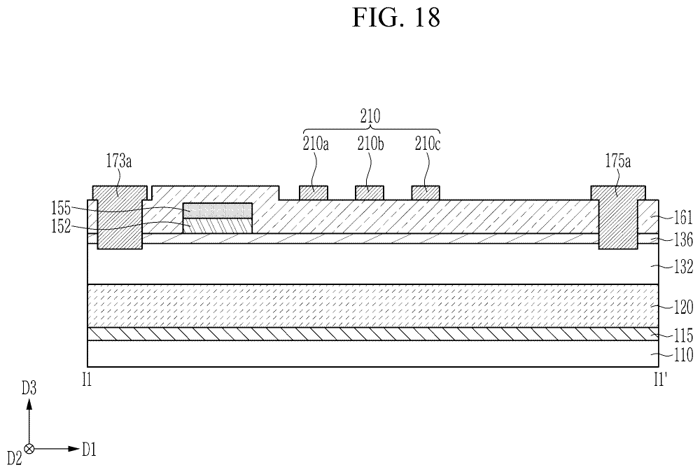

As shown in FIG. 18, a conductive material may be deposited on the first passivation layer 161 on which the first trench 141 and the second trench 143 are formed, and it may be patterned to form a first source electrode 173a, a first drain electrode 175a, and lower field distribution patterns 210. In some example embodiments, the first source electrode 173a, the first drain electrode 175a, and the lower field distribution patterns 210 may be simultaneously formed by the same process. For example, a conductive material may be deposited on the upper surface of the first passivation layer 161 on which the first trench 141 and the second trench 143 are formed, and the conductive material may be patterned according to the photo and etching process to simultaneously form the first source electrode 173a, the first drain electrode 175a, and the lower field distribution patterns 210.

The first source electrode 173a and the first drain electrode 175b may include a conductive material. For example, the first source electrode 173a and the first drain electrode 175a may include a metal, a metal alloy, a conductive metal nitride, a metal silicide, a doped semiconductor material, a conductive metal oxide, or a conductive metal oxynitride. The first source electrode 173a and the first drain electrode 175a may be a single layer or a multilayer. For example, conductive layers including different materials may be stacked, and they may be patterned to form the first source electrode 173a and the first drain electrode 175a. The conductive layers may be simultaneously or sequentially etched using a mask pattern.

The first source electrode 173a may fill the first trench 141 (refer to FIG. 17). The first source electrode 173a may contact the channel layer 132 and the barrier layer 136 in the first trench 141 (refer to FIG. 17). The first source electrode 173a may contact the lateral surfaces of the channel layer 132 and the barrier layer 136. The first source electrode 173a may cover the lateral surfaces of the channel layer 132 and the barrier layer 136. The first source electrode 173a may be electrically connected to the channel layer 132 through the first trench 141. The upper surface of the first source electrode 173a may further protrude than the upper surface of the first passivation layer 161.

The first drain electrode 175a may fill the second trench 143 (refer to FIG. 17). The first drain electrode 175a may contact the channel layer 132 and the barrier layer 136 in the second trench 143 (refer to FIG. 17). The first drain electrode 175a may contact the lateral surfaces of the channel layer 132 and the barrier layer 136. The first drain electrode 175a may cover the lateral surfaces of the channel layer 132 and the barrier layer 136. The first drain electrode 175a may be electrically connected to the channel layer 132 through the second trench 143. The upper surface of the first drain electrode 175a may further protrude than the upper surface of the first passivation layer 161.

The first source electrode 173a and the first drain electrode 175a may ohmic-contact the channel layer 132. The region contacting the first source electrode 173a and the first drain electrode 175a in the channel layer 132 may be doped in relatively higher concentration than other regions. For example, the channel layer 132 may be doped by an ion implanting process or an annealing process. Without being limited to this, the process for doping the channel layer 132 may include various processes. The process for doping the channel layer 132 may be performed prior to formation of the first source electrode 173a and the first drain electrode 175a. Depending on cases, the channel layer 132 may not be doped.

The 2-dimensional electron gas 134 may be formed on the portion disposed near the barrier layer 136 in the channel layer 132. The 2-dimensional electron gas 134 may be disposed on an interface between the channel layer 132 and the barrier layer 136. The 2-dimensional electron gas 134 may be disposed in the drift region DTR (refer to FIG. 2) between the first source electrode 173a and the first drain electrode 175a. The depletion region DPR (refer to FIG. 2) may be formed in the channel layer 132 by the gate semiconductor layer 152 with the different energy band gap from the barrier layer 136. Therefore, the semiconductor device may have a normally-off characteristic. That is, the semiconductor device may be a normally-off high electron mobility transistor (HEMT). In the gate Off state, the 2-dimensional electron gas 134 may be disposed in the drift region DTR excluding the depletion region DPR (refer to FIG. 2) of the channel layer 132. In the gate On state, the flow of the 2-dimensional electron gas 134 is continuously supplied in the depletion region DPR (refer to FIG. 2) so the 2-dimensional electron gas 134 may be disposed in the drift region DTR.

The lower field distribution patterns 210 may be a single layer or a multilayer. For example, the conductive layers including different materials may be stacked and may then be patterned to form the lower field distribution patterns 210. The conductive layers may be simultaneously or sequentially etched using a mask pattern. The lower field distribution patterns 210 may include the same material as the source electrode 173 and the drain electrode 175.

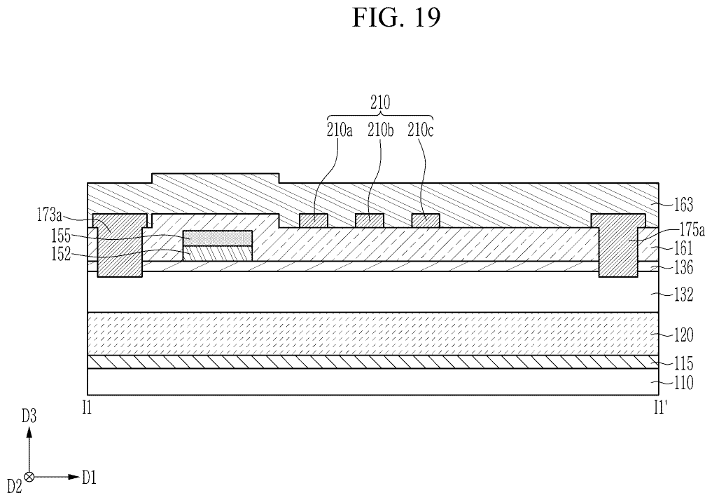

As shown in FIG. 19, the second passivation layer 163 may be deposited on the first passivation layer 161, the source electrode 173, the drain electrode 175, and the lower field distribution patterns 210. The second passivation layer 163 may protect the source electrode 173, the drain electrode 175, and the lower field distribution patterns 210 from the outside. In some example embodiments, the respective lower field distribution patterns 210 may be surrounded by the first passivation layer 161 and the second passivation layer 163. Hence, the lower field distribution patterns 210 may float, respectively.

The second passivation layer 163 may cover the upper surface of the first passivation layer 161, and the upper surfaces and the lateral surfaces of the source electrode 173, the drain electrode 175, and the lower field distribution patterns 210. The second passivation layer 163 may include an insulating material. For example, the second passivation layer 163 may include a material such as SiO₂, SiN, SiON, or Al₂O₃. In some example embodiments, the second passivation layer 163 may include the same material as the first passivation layer 161. In this case, the boundary between the second passivation layer 163 and the first passivation layer 161 may not be seen.

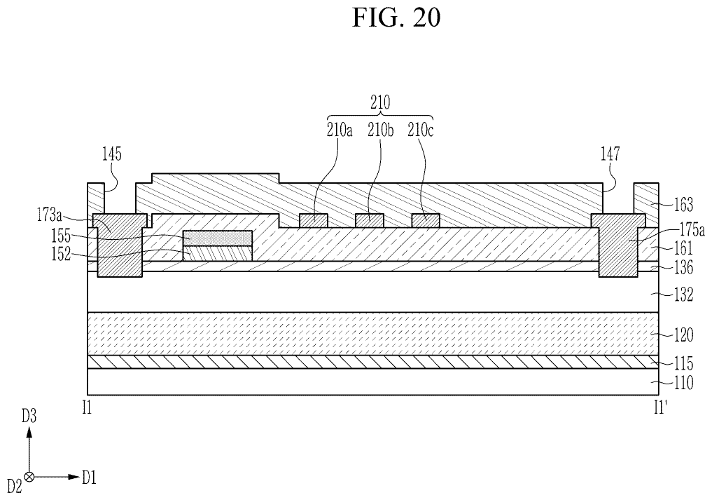

As shown in FIG. 20, the first opening 145 and the second opening 147 may be formed by patterning a region such as a predetermined region of the second passivation layer 163 using a photo and etching process. The first opening 145 may be formed in the region overlapping the first source electrode 173a in the third direction D3. A portion of the upper surface of the first source electrode 173a may be exposed by the first opening 145. The second opening 147 may be formed in the region overlapping the first drain electrode 175a in the third direction D3. A portion of the upper surface of the first drain electrode 175a may be exposed by the second opening 147.

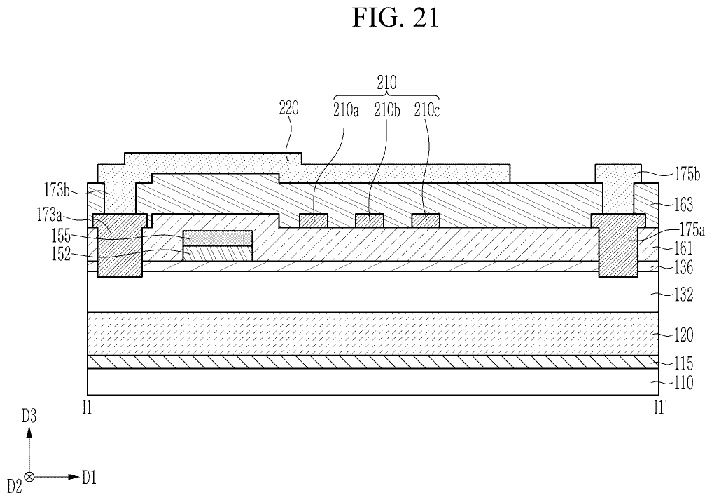

As shown in FIG. 21, a conductive material may be deposited on the second passivation layer 163, and the conductive material may be patterned according to a photo and etching process, second source electrode 173b to form the second drain electrode 175b and the upper field distribution pattern 220.

A conductive material may be deposited on the entire upper surface of the second passivation layer 163. The first opening 145 (refer to FIG. 20) and the second opening 147 (refer to FIG. 20) may be filled with the conductive material. The second source electrode 173b, the second drain electrode 175b, and the upper field distribution pattern 220 may be formed by removing a region such as a predetermined region of the conductive material deposited on the second passivation layer 163 using a photo and etching process. Referring to FIG. 21, the upper field distribution pattern 220 may be patterned to cover the gate electrode 155 and the lower field distribution patterns 210. The upper field distribution pattern 220 may overlap the lower field distribution patterns 210 in the third direction D3.

In some example embodiments, the second source electrode 173b may be formed by filling the first opening 145 (refer to FIG. 20) with a conductive material, and hence, the upper field distribution pattern 220 may be electrically connected to the first source electrode 173a through the second source electrode 173b. When the upper field distribution pattern 220 and the second source electrode 173b include the same conductive material as the first source electrode 173a, the boundary between the second source electrode 173b and the first source electrode 173a may not be seen.

In some example embodiments, the second drain electrode 175b may be formed by filling the second opening 147 (refer to FIG. 20) with the conductive material. When the second drain electrode 175b includes the same conductive material as the first drain electrode 175a, the boundary between the second drain electrode 175b and the first drain electrode 175a may not be seen.

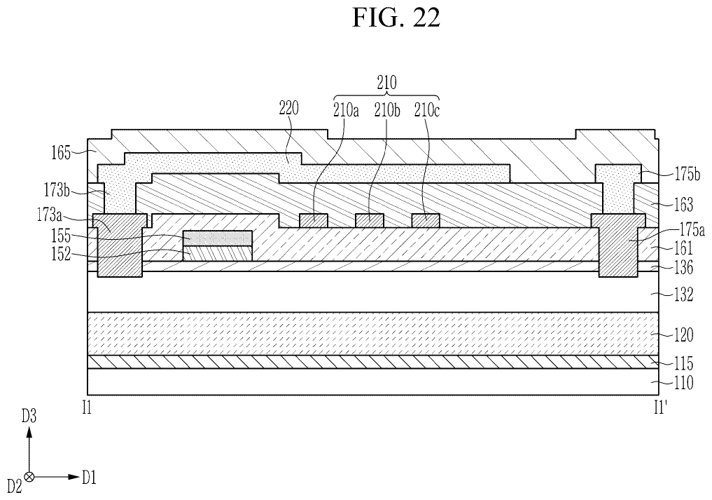

As shown in FIG. 22, the semiconductor device described with reference to FIG. 1 to FIG. 3 may be manufactured by forming a third passivation layer 165 on the second passivation layer 163 and the upper field distribution pattern 220.

The third passivation layer 165 may cover the upper surface of the second passivation layer 163. The third passivation layer 165 may cover the upper surface and the lateral surface of the upper field distribution pattern 220. The third passivation layer 165 may include an insulating material. For example, the third passivation layer 165 may include a material such as polyimide (PI), SiO₂, SiN, or SiON. The third passivation layer 165 may be a single layer or a multilayer. The third passivation layer 165 may be disposed on the outermost side of the semiconductor device, and may protect the inside of the device from the outside.

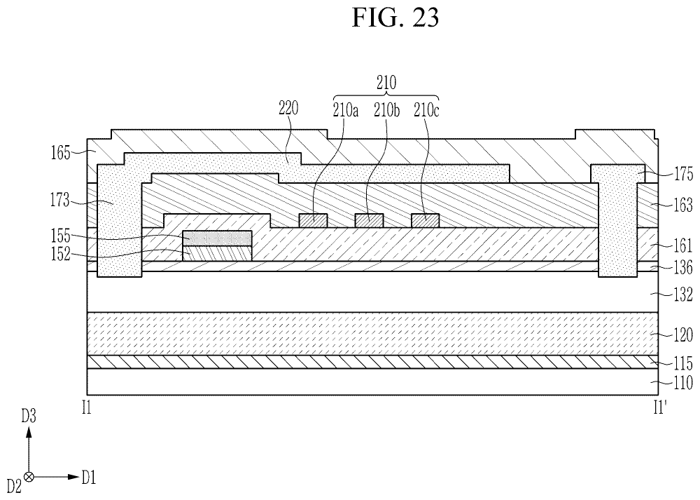

FIG. 23 shows a cross-sectional view of a semiconductor device manufactured by a manufacturing process that is different from a manufacturing process described with reference to FIG. 14 to FIG. 22.

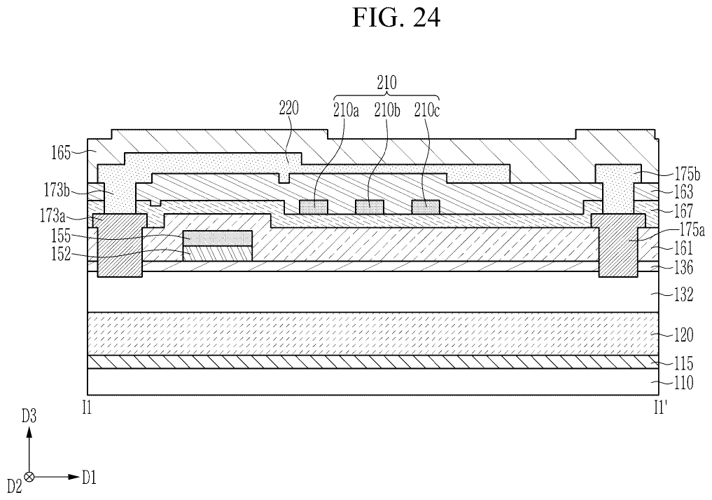

Regarding the semiconductor device shown in FIG. 23, the source electrode 173, the drain electrode 175, and the upper field distribution pattern 220 may be simultaneously formed according to the same process. The seed layer 115, the buffer layer 120, the channel layer 132, the barrier layer 136, the gate semiconductor layer 152, and the gate electrode 155 may be formed on the substrate 110, and the first passivation layer 161 for covering the barrier layer 136 and the gate electrode 155 may be formed. A conductive material may be deposited on the first passivation layer 161, and it may be patterned to form the lower field distribution patterns 210 spaced and arranged in the first direction D1. The second passivation layer 163 may be deposited on the first passivation layer 161 and the lower field distribution pattern 210, and region such as a predetermined regions of the second passivation layer 163, the first passivation layer 161, the barrier layer 136, and the channel layer 132 may be sequentially etched to form trenches disposed on respective sides of the gate electrode 155. The trenches may be filled with the conductive material, and it may be patterned to simultaneously form the source electrode 173, the upper field distribution pattern 220, and the drain electrode 175. The semiconductor device shown in FIG. 24 may be manufactured by depositing the third passivation layer 165 on the second passivation layer 163 and the upper field distribution pattern 220.

FIG. 24 shows a cross-sectional view of a semiconductor device manufactured according to a manufacturing process that is different from a manufacturing process described with reference to FIG. 14 to FIG. 22 and a manufacturing process described with reference to FIG. 23. The process for manufacturing a semiconductor device shown in FIG. 24 mostly corresponds to the above-described example embodiments so differences from the same will be mainly described.

Regarding the semiconductor device shown in FIG. 24, the first source electrode 173a, the first drain electrode 175a, and the lower field distribution patterns 210 may not be simultaneously formed. In detail, the first source electrode 173a and the first drain electrode 175a may be formed, and the lower field distribution patterns 210 may then be formed.

In detail, the first and second trenches 141 and 143 (refer to FIG. 17) may be formed on the first passivation layer 161, and the conductive material may be deposited on the entire upper surface of the first passivation layer 161 on which the first and second trenches 141 and 143 (refer to FIG. 17) are formed. The first and second trenches 141 and 143 (refer to FIG. 17) may be filled with the conductive material. The first source electrode 173a and the first drain electrode 175a may be formed according to the photo and etching process.

A fourth passivation layer 167 for covering the upper surface of the first passivation layer 161 and a portion of the upper surfaces and the lateral surfaces of the first source electrode 173a and the first drain electrode 175a may be formed. The fourth passivation layer 167 may include the same material as the first passivation layer 161 and/or the second passivation layer 163. The conductive material may be deposited on the fourth passivation layer 167, and a region such as a predetermined region of the conductive material may be removed by the photo and etching process to form the lower field distribution patterns 210 spaced and arranged in the first direction D1. The lower field distribution pattern 210 may include a different conductive material from the first source electrode 173a and the first drain electrode 175a, or may include the same material as them. The next process is the same as or similar to the manufacturing process described with reference to FIG. 14 to FIG. 22 so no detailed descriptions thereof will be provided.

While inventive concepts been described in connection with what is considered to be some example embodiments, it is to be understood that the disclosure is not limited to the disclosed example embodiments, but, on the contrary, is intended to cover various modifications and equivalent arrangements included within the spirit and scope of the appended claims. Additionally, example embodiments are not necessarily mutually exclusive. For example, some example embodiments may include one or more features described with reference to one or more figures, and may also include one or more other features described with reference to one or more other figures.

What is claimed is:

1. A semiconductor device comprising:
a channel layer;
a barrier layer on the channel layer;
a gate electrode on the barrier layer;
a source electrode and a drain electrode connected to the channel layer and on respective sides of the gate electrode;
lower field distribution patterns spaced between the gate electrode and the drain electrode; and
an upper field distribution pattern spaced from the lower field distribution patterns and on the lower field distribution patterns, and connected to the source electrode.

2. The semiconductor device of claim 1, wherein
the lower field distribution patterns are configured to float during operation of the semiconductor device.

3. The semiconductor device of claim 1, wherein
the lower field distribution patterns are spaced from each other in a first direction, and
the lower field distribution patterns respectively extend in a second direction crossing the first direction.

4. The semiconductor device of claim 3, wherein
at least a region of the lower field distribution patterns at least partially overlaps the upper field distribution pattern in a third direction perpendicular to the first direction and the second direction.

5. The semiconductor device of claim 4, wherein
the lower field distribution patterns include a first lower field distribution pattern, a second lower field distribution pattern, and a third lower field distribution pattern sequentially arranged in the first direction.

6. The semiconductor device of claim 5, wherein
the first lower field distribution pattern at least partially overlaps the upper field distribution pattern in the third direction, and
a region of the second lower field distribution pattern and the third lower field distribution pattern at least partially overlaps the upper field distribution pattern in the third direction.

7. The semiconductor device of claim 5, wherein
the first lower field distribution pattern at least partially overlaps the upper field distribution pattern in the third direction by a first area,
the second lower field distribution pattern at least partially overlaps the upper field distribution pattern in the third direction by a second area less than the first area, and
the third lower field distribution pattern at least partially overlaps the upper field distribution pattern in the third direction by a third area less than the second area.

8. The semiconductor device of claim 5, wherein
an area in which the upper field distribution pattern at least partially overlaps the respective lower field distribution patterns in the third direction is gradually reduced in accordance with a distance to the first direction.

9. The semiconductor device of claim 5, wherein
a width of the upper field distribution pattern in the second direction has,
a first width in a region at least partially overlapping the first lower field distribution pattern in the third direction,
a second width less than the first width in a region at least partially overlapping the second lower field distribution pattern in the third direction, and
a third width less than the second width in a region at least partially overlapping the third lower field distribution pattern in the third direction.

10. The semiconductor device of claim 9, wherein
a width of the upper field distribution pattern in the second direction has,
a first width in a region at least partially overlapping the first lower field distribution pattern in the third direction, and
a second width less than the first width in a region at least partially overlapping the second lower field distribution pattern and the third lower field distribution pattern in the third direction.

11. The semiconductor device of claim 5, wherein
the upper field distribution pattern defines a hole region penetrating the upper field distribution pattern in the third direction,
wherein the hole region is on one of the second lower field distribution pattern and the third lower field distribution pattern.

12. The semiconductor device of claim 5, wherein
the upper field distribution pattern at least partially overlaps a region of the third lower field distribution pattern in the third direction, and
an end of the upper field distribution pattern near the drain electrode is on an upper surface of the third lower field distribution pattern.

13. The semiconductor device of claim 5, wherein
an end of the upper field distribution pattern nearer to the drain electrode than to the source electrode is on an upper surface of the second lower field distribution pattern, and
the semiconductor device further includes a protruding region extending from the end in the first direction, and at least partially overlapping a region of the third lower field distribution pattern in the third direction.

14. The semiconductor device of claim 13, wherein
the protruding region is integral with the upper field distribution pattern.

15. The semiconductor device of claim 5, wherein
a gap between the first lower field distribution pattern and the second lower field distribution pattern is different from a gap between the second lower field distribution pattern and the third lower field distribution pattern.

16. The semiconductor device of claim 3, wherein
the lower field distribution patterns have different widths in the second direction.

17. A method for manufacturing a semiconductor device comprising:
forming a channel layer on a substrate;
forming a barrier layer on the channel layer;
forming a gate semiconductor layer on the barrier layer;
forming a first passivation layer covering the barrier layer and the gate semiconductor layer;
forming lower field distribution patterns spaced from each other and on the first passivation layer in the first direction;
forming a second passivation layer covering the lower field distribution patterns; and
forming upper field distribution patterns at least partially overlapping at least a region of the lower field distribution patterns in a thickness direction on the second passivation layer.

18. The method of claim 17, wherein
the lower field distribution patterns are formed together according to a same process.

19. A semiconductor device comprising:
a substrate;
a buffer layer on the substrate;
a channel layer on the buffer layer;
a barrier layer on the channel layer;
a gate electrode on the barrier layer;
a gate semiconductor layer between the barrier layer and the gate electrode;
a first passivation layer disposed on the barrier layer, and covering the gate electrode and the gate semiconductor layer;
lower field distribution patterns between the gate electrode and a drain electrode on the first passivation layer, and spaced from each other and arranged in a first direction;
a second passivation layer covering the lower field distribution patterns;
a source electrode and a drain electrode penetrating the first passivation layer and the second passivation layer, connected to the channel layer, and on respective sides of the gate electrode; and
an upper field distribution pattern spaced from the lower field distribution patterns and on the lower field distribution patterns, and connected to the source electrode.

20. The semiconductor device of claim 19, wherein
the lower field distribution patterns extend in a second direction crossing the first direction, and
at least a region of the lower field distribution patterns at least partially overlaps the upper field distribution pattern in a third direction perpendicular to the first direction and the second direction.
